(19) United States
(12) Patent Application Publication
(10) Pub. No.: US 2026/0334187 A1
(43) Pub. Date: Oct. 22, 2026

(54) STACKED CAPACITOR STRUCTURE AND METHOD OF FABRICATION THEREOF

(71) Applicant: Taiwan Semiconductor Manufacturing Company, Ltd., Hsin-Chu (TW)

(72) Inventors: Pin-Shun DING, Taichung City (TW); Tzu-Ting LIU, Taoyuan City (TW); Hsiang-Ku SHEN, Hsinchu City (TW); Ying-Han CHIOU, Tainan City (TW)

(21) Appl. No.: 19/398,671

(22) Filed: Nov. 24, 2025

Related U.S. Application Data
(60) Provisional application No. 63/790,553, filed on Apr. 17, 2025.

(51) Int. Cl. H10W 20/20; H10D 1/68; H10W 20/00; H10W 90/00

(52) U.S. Cl. CPC H10W 20/20; H10D 1/68; H10W 20/023; H10W 90/00

(57) ABSTRACT

Stacked capacitor structures are disclosed herein. In some embodiments, a method of fabricating a capacitor structure includes forming a first capacitor stack and a second capacitor stack in a passivation structure. The first capacitor stack and the second capacitor stack may each include a pillar metal-insulator-metal (MIM) stack and a trench MIM stack. The method further includes forming a metal structure (e.g., a bottom metal plate, a middle metal plate, a top metal plate, or combinations thereof) on an electrode of the first capacitor stack, an electrode of second capacitor stack, or both. The method further include forming a via structure to the first capacitor stack, the second capacitor stack, and the metal structure. The via structure may extend through the first capacitor stack, the second capacitor stack, and the metal structure.

This application is a non-provisional application of and claims benefit of U.S. Provisional Patent Application Serial No. 63/790,553, filed Apr. 17, 2025, the entire disclosure of which is incorporated herein by reference.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

For example, ICs often implement metal-insulator-metal (MIM) capacitors, and to increase a MIM capacitor’s capacitance, an area (and thus a size) of the MIM capacitor is generally enlarged as well. As ICs and their semiconductor devices scale to more advanced (e.g., smaller) technology nodes, the area required to provide MIM capacitors that exhibit the desired, higher capacitances needed for improving IC performance has become a challenge. Improvements in MIM capacitors and methods of fabrication thereof are thus needed.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIGS. 1–16 are diagrammatic cross-sectional views of various embodiments of integrated circuit (IC) structures, in portion or entirety, that include a stacked capacitor structure, according to various aspects of the present disclosure.

FIG. 17A is an enlarged, diagrammatic cross-sectional view of a portion of a stacked capacitor structure of an IC structure, such as the stacked capacitor structure of the IC structure of FIG. 1, according to various aspects of the present disclosure.

FIG. 17B is a simplified diagrammatic view of the portion of the stacked capacitor structure of FIG. 17A according to various aspects of the present disclosure.

FIG. 18A is an enlarged, diagrammatic cross-sectional view of a portion of a stacked capacitor structure of an IC structure, such as the stacked capacitor structure of the IC structure of FIG. 2, according to various aspects of the present disclosure.

FIG. 18B is a simplified diagrammatic view of the portion of the stacked capacitor structure of FIG. 18A according to various aspects of the present disclosure.

FIGS. 19A–19F are diagrammatic top views of various embodiments of stacked capacitor structures, in portion or entirety, of IC structures, such as the IC structures of FIGS. 1–14, according to various aspects of the present disclosure.

FIGS. 20A–20D are diagrammatic top views of various embodiments of stacked capacitor structures, in portion or entirety, of IC structures, such as the IC structures of FIGS. 1–14, according to various aspects of the present disclosure.

FIG. 21 is a diagrammatic top view of a stacked capacitor structure, in portion or entirety, of an IC structure, such as the stacked capacitor structures of the IC structures of FIGS. 1–14, according to various aspects of the present disclosure.

FIGS. 22A–22K are diagrammatic cross-sectional views of an IC structure, in portion or entirety, such as the IC structure of FIG. 1, at various stages of fabrication of a stacked capacitor structure thereof according to various aspects of the present disclosure.

FIGS. 23A–23L are diagrammatic cross-sectional views of an IC structure, in portion or entirety, such as the IC structure of FIG. 2, at various stages of fabrication of a stacked capacitor structure thereof according to various aspects of the present disclosure.

### DETAILED DESCRIPTION

The present disclosure relates generally to an integrated circuit (IC) structure and a method of fabrication thereof, and more particularly, to a stacked capacitor structure, which may be integrated with other devices and/or form a portion of an IC structure.

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, spatially relative terms, for example, “lower,” “upper,” “horizontal,” “vertical,” “above,” “over,” “below,” “beneath,” “up,” “down,” “top,” “bottom,” etc. as well as derivatives thereof (e.g., “horizontally,” “downwardly,” “upwardly,” etc.) are used for ease of the present disclosure of one features relationship to another feature. The spatially relative terms are intended to cover different orientations of the device including the features. The present disclosure may also repeat reference numerals and/or letters in the various examples. This repetition is for the purpose of simplicity and clarity and does not in itself dictate a relationship between the various embodiments and/or configurations discussed.

Further, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/–20 % of the number described, based on known manufacturing tolerances associated with manufacturing a feature having a characteristic associated with the number. For example, a material layer having a thickness of “about 5 nm” can encompass a dimension range from 4.5 nm to 5.5 nm where manufacturing tolerances associated with depositing the material layer are known to be +/–1 0 % by one of ordinary skill in the art. Furthermore, given the variances inherent in any manufacturing process, when device features are described as having “substantial” properties and/or characteristics, such term is intended to capture properties and/or characteristics that are within tolerances of manufacturing processes. For example, “substantially vertical” or “substantially horizontal” features are intended to capture features that are approximately vertical and horizontal within given tolerances of the manufacturing processes used to fabricate such features – but not mathematically or perfectly vertical and horizontal.

Stacked capacitor structures disclosed herein include an electrically conductive structure, such as one or more additional metal plate/layers, connected to an electrode (or electrodes) of the stacked capacitor structures. The electrically conductive structure may be and/or include a top metal plate (e.g., formed above and/or on a capacitor stack, such as on a top electrode thereof, of a stacked capacitor structure), a middle metal plate (e.g., formed between a first capacitor stack and a second capacitor stack of a stacked capacitor structure, such as between a bottom electrode and a top electrode, respectively, of the first capacitor stack and a second capacitor stack), a bottom metal plate (e.g., formed under and/or on a capacitor stack, such as on a bottom electrode thereof, of a stacked capacitor structure), or combinations thereof. Inserting an additional, extra metal plate into the stacked capacitor structures may reduce resistance associated therewith, thereby increasing device speed (e.g., by improving transmission of electrical signals to/from and/or through the stacked capacitor structure). Details of the proposed stacked capacitor structure and methods of fabrication thereof are described herein. From the description, it may be seen that the disclosed stacked capacitor structures offer various advantages. It is understood, however, that the various embodiments of the disclosed stacked capacitor structures may offer additional advantages, and not all advantages are necessarily disclosed herein, and that no particular advantage is required for all embodiments.

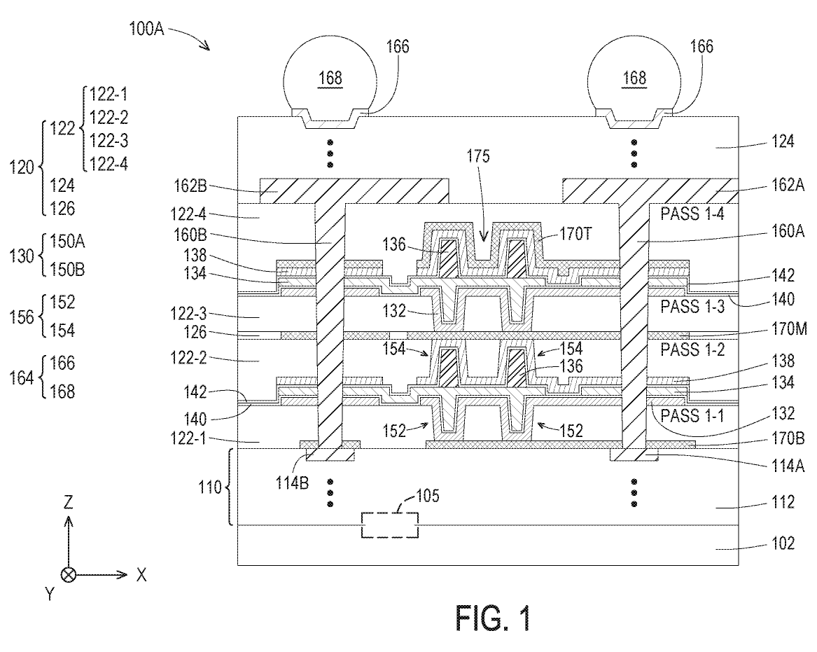

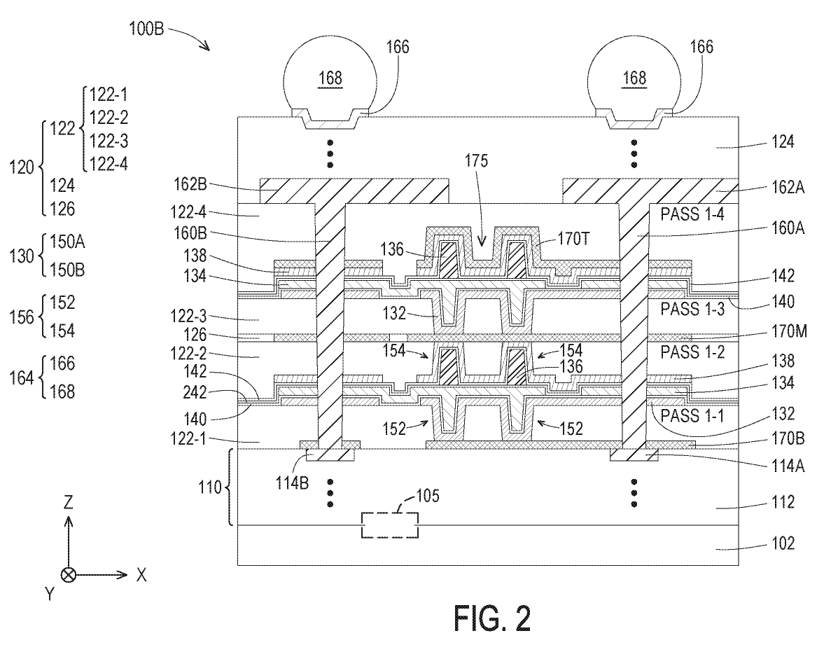

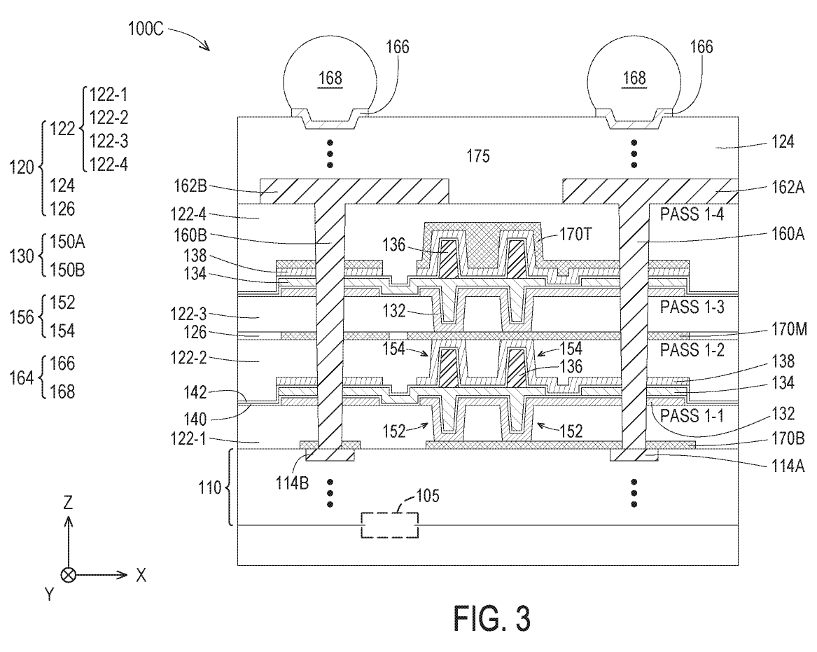

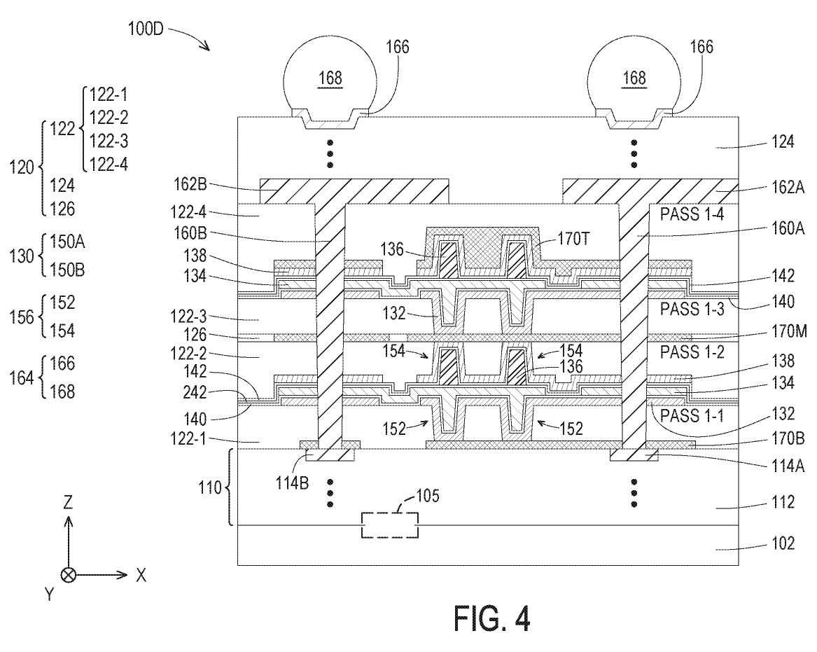

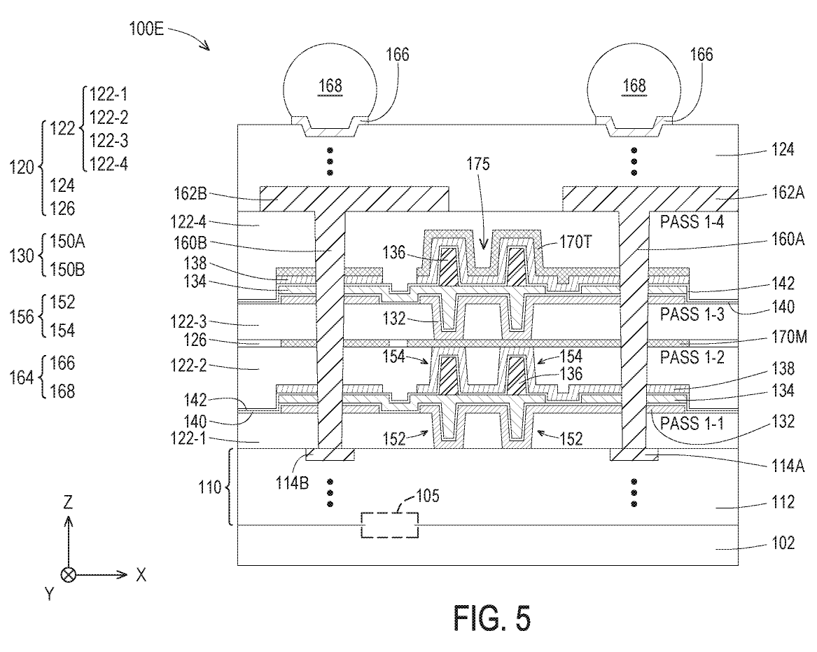

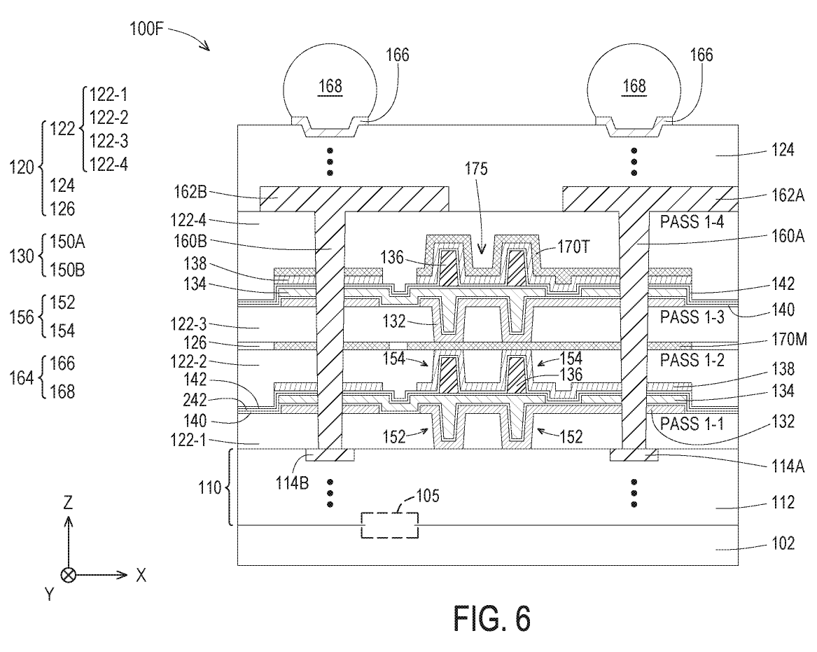

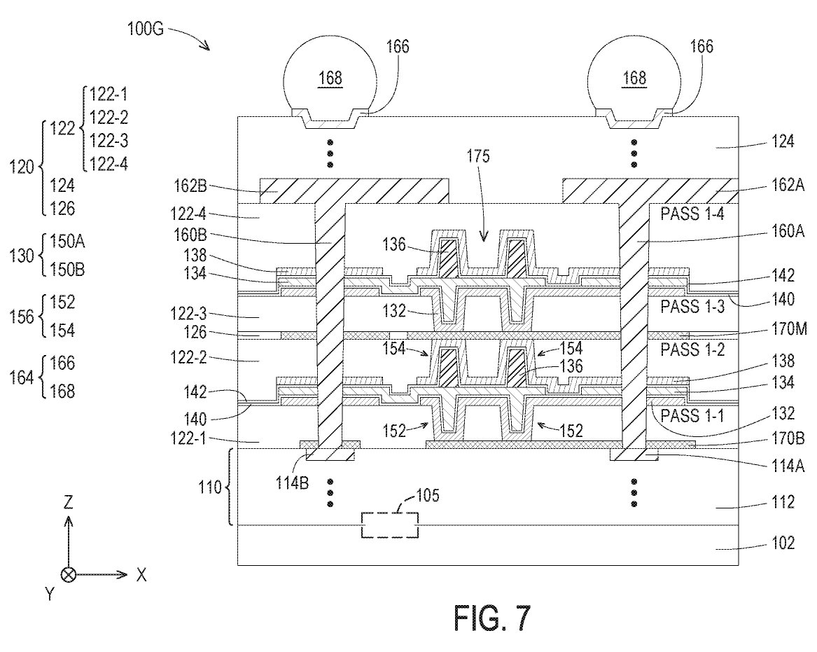

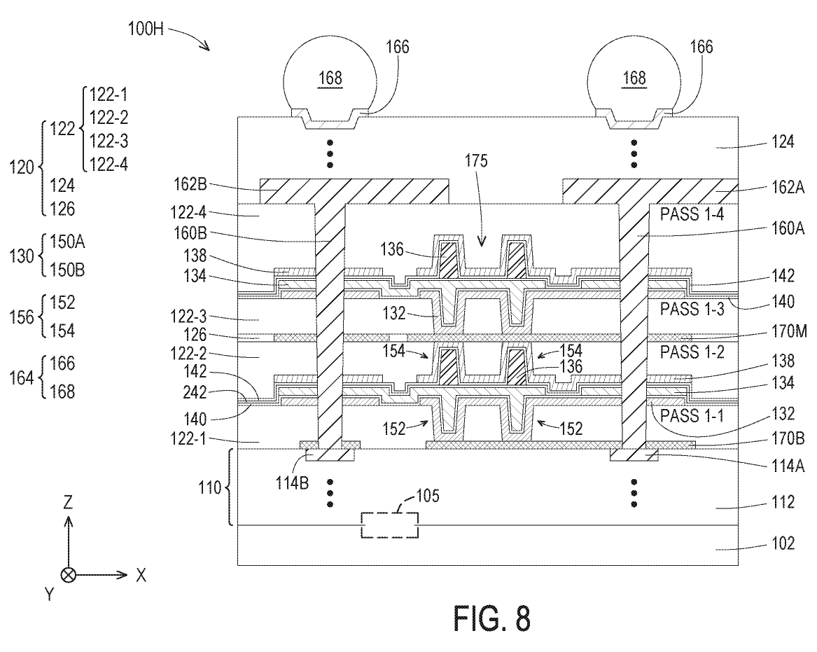

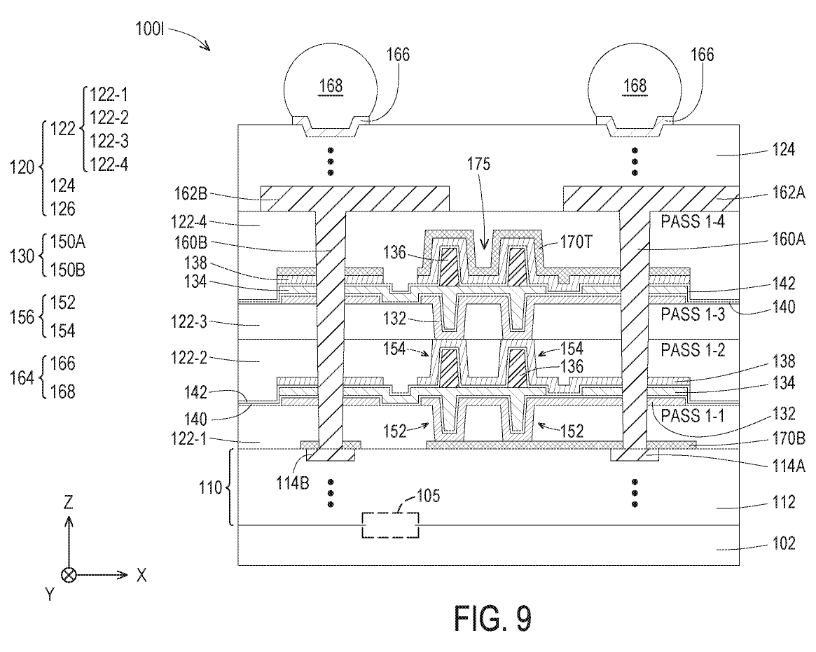

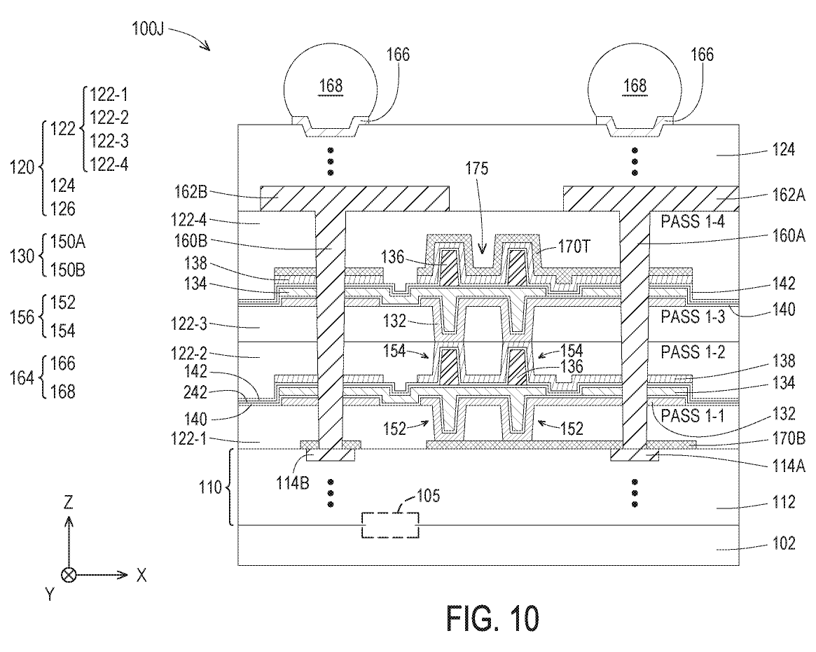

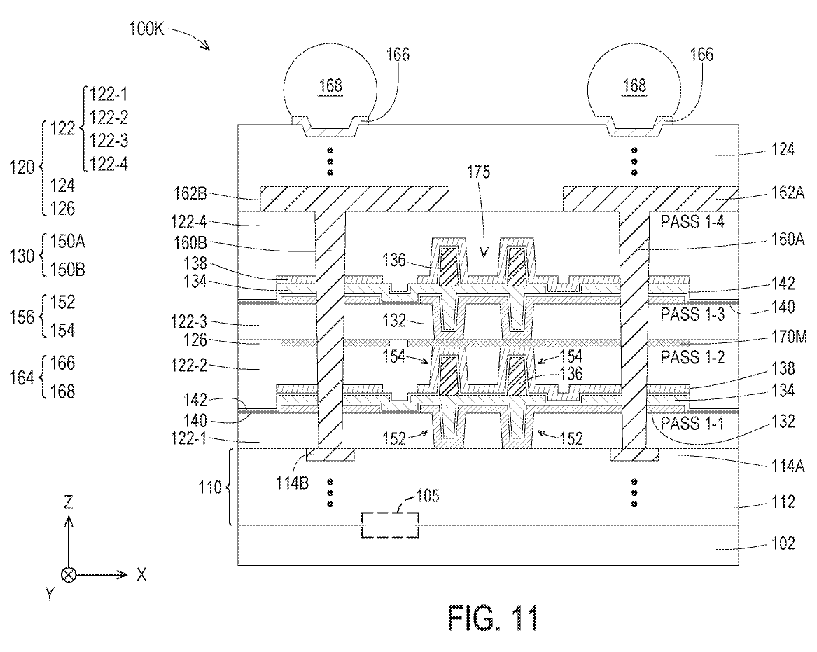

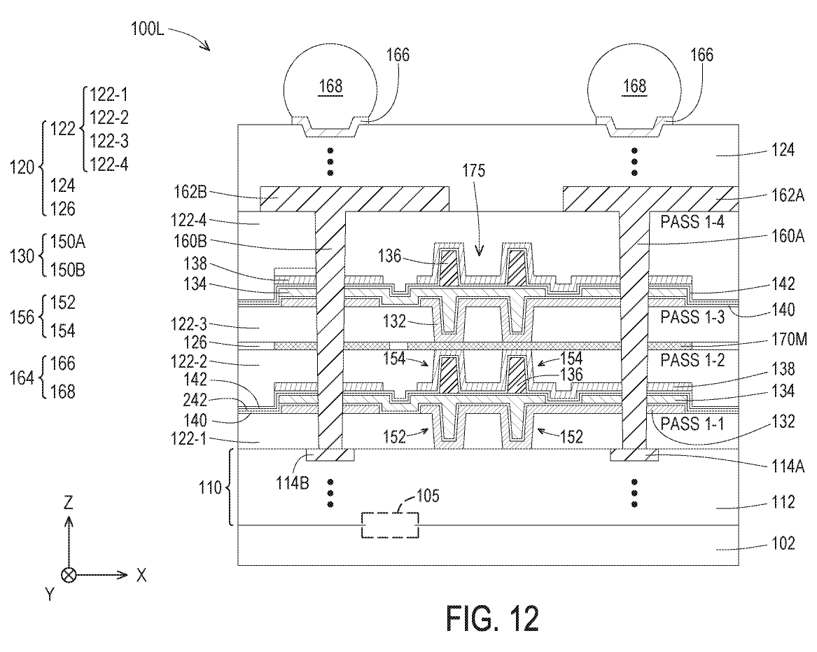

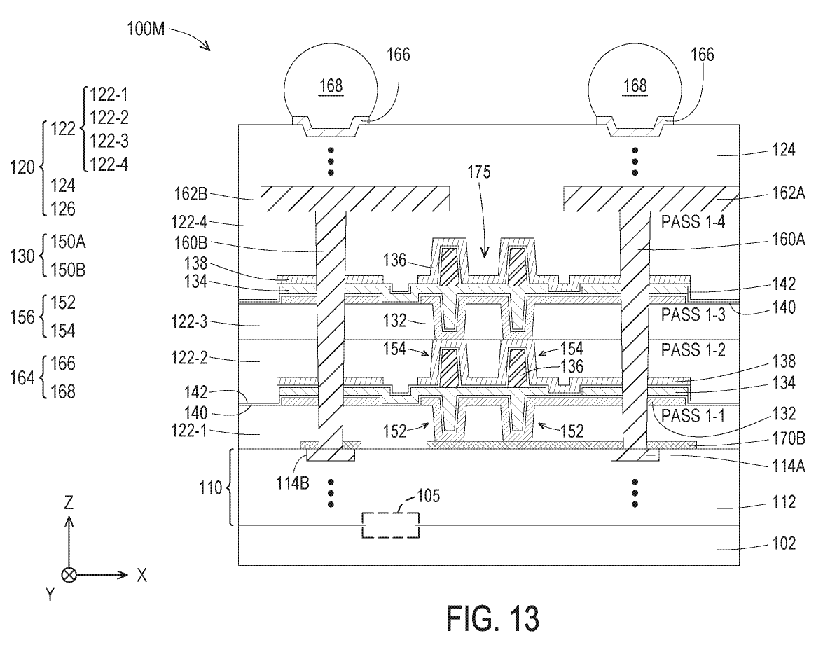

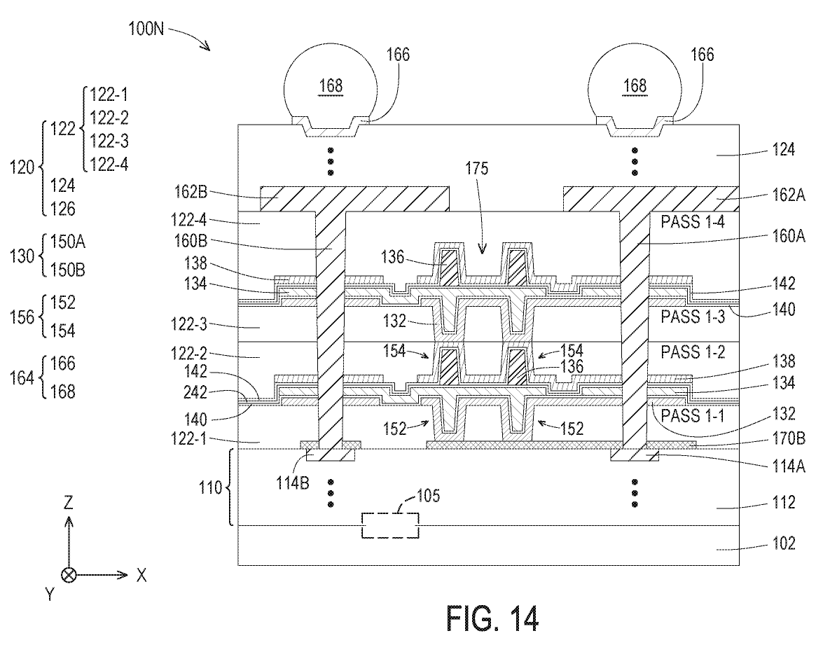

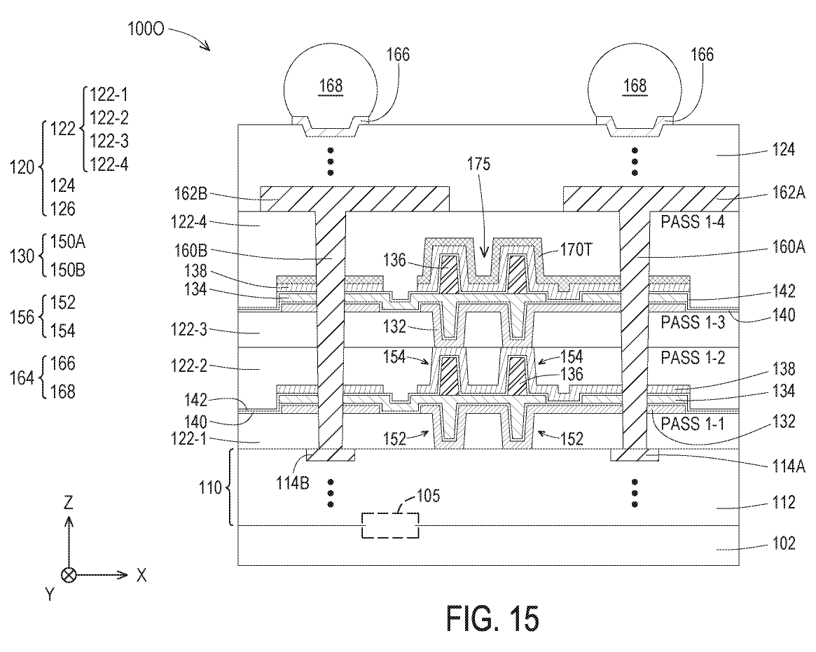

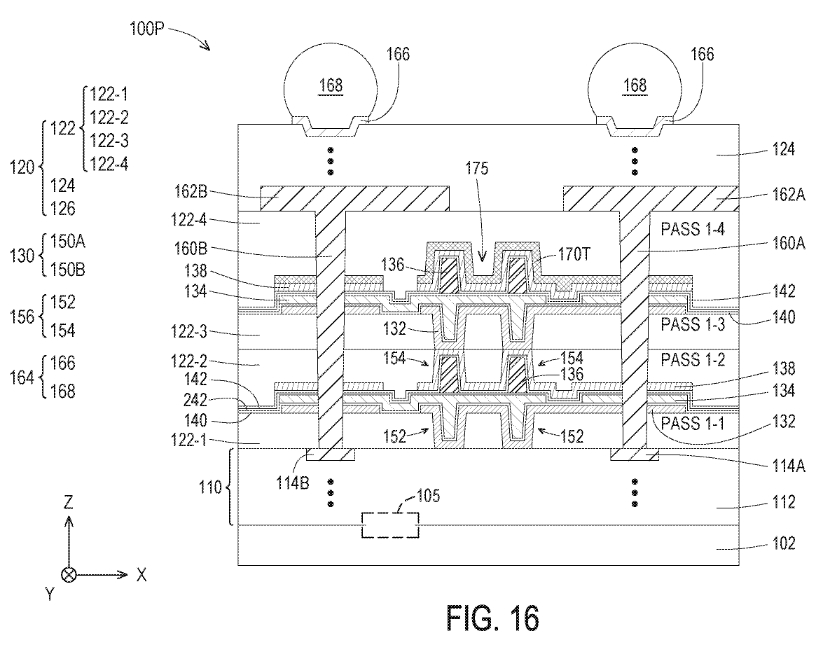

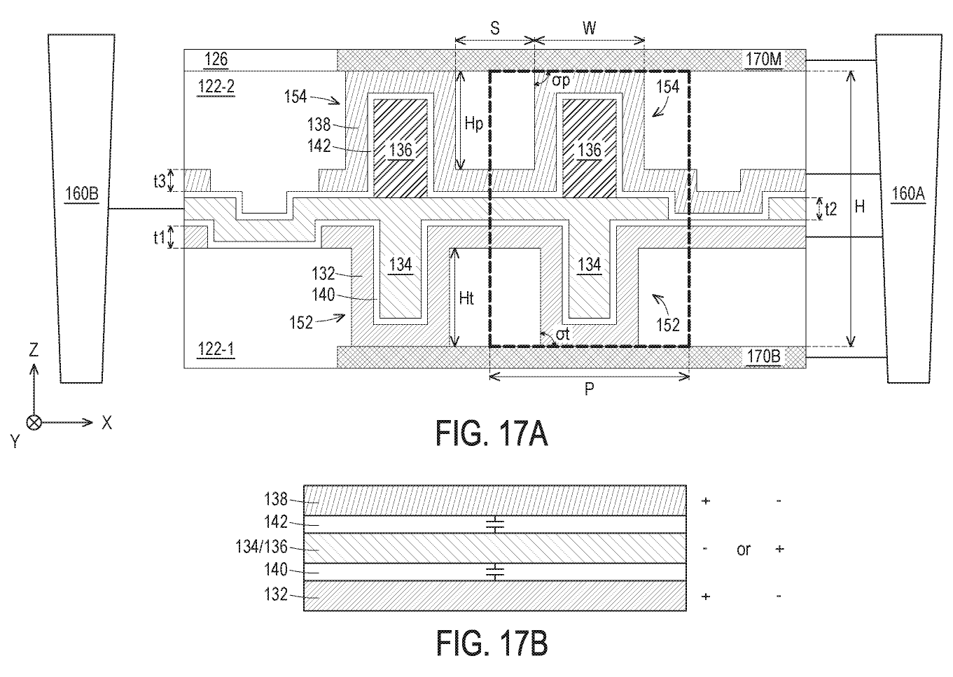

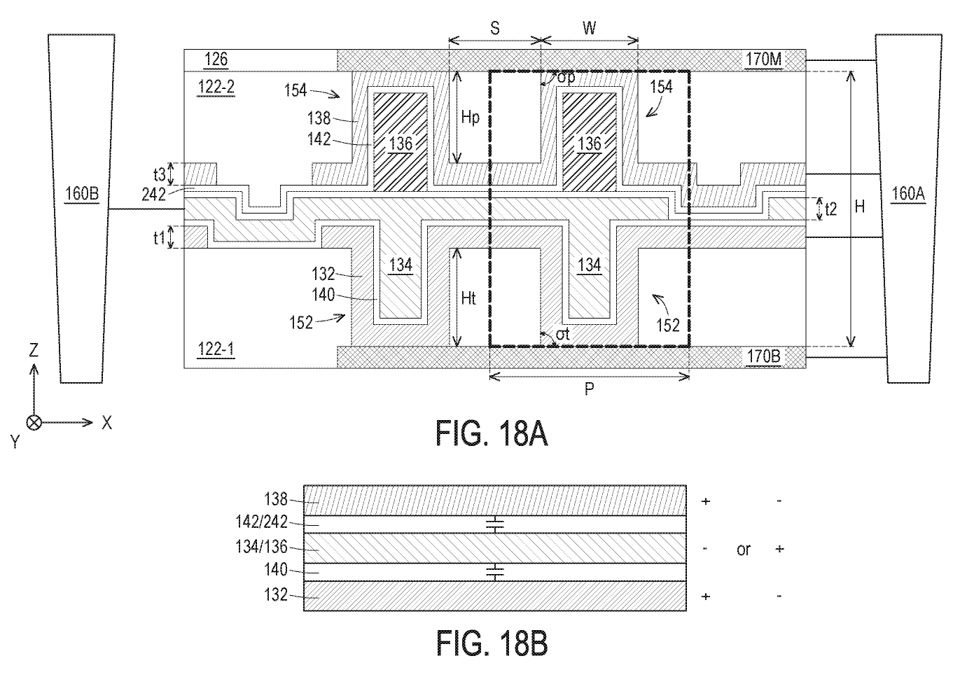

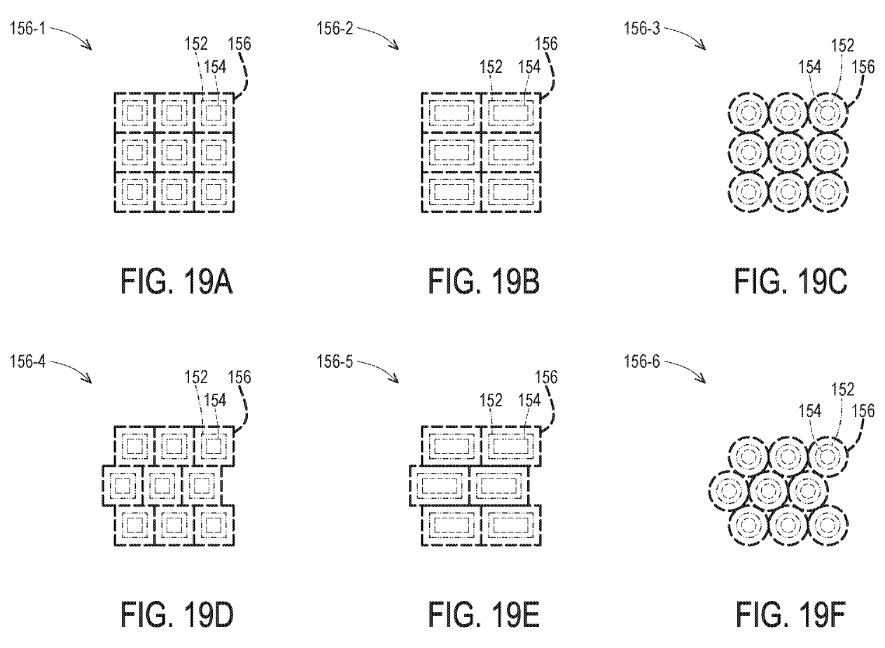

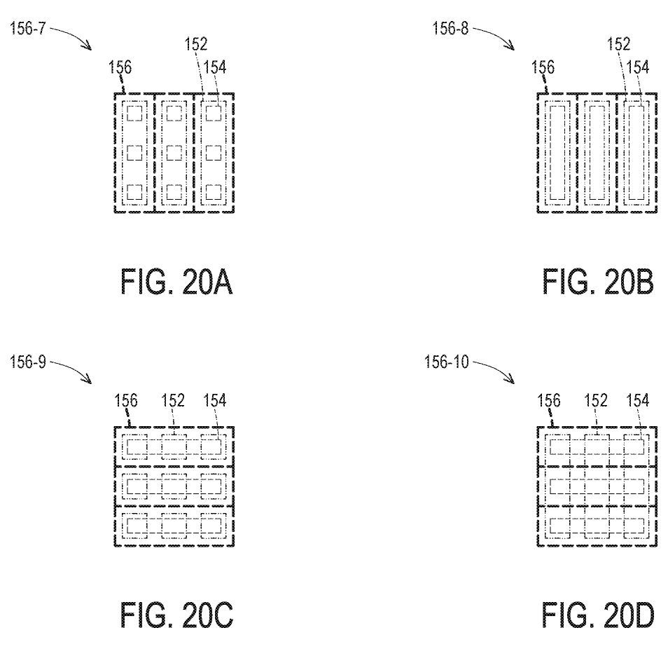

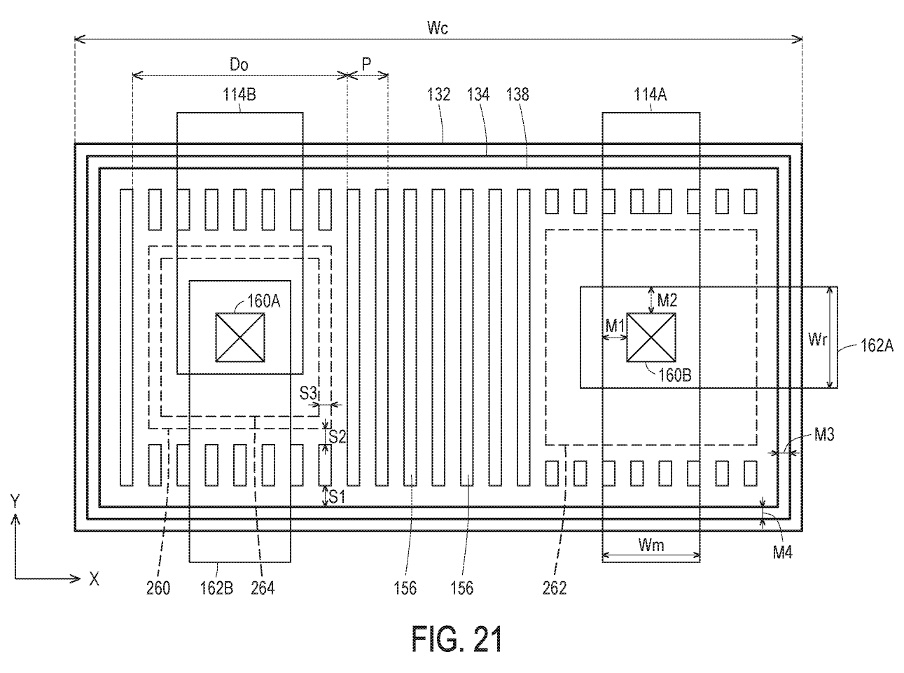

FIGS. 1–16 are cross-sectional views of integrated circuit (IC) structures, in portion or entirety, that include stacked capacitor structures, according to various aspects of the present disclosure. For example, FIG. 1 depicts an IC structure 100A, FIG. 2 depicts an IC structure 100B, FIG. 3 depicts an IC structure 100C, FIG. 4 depicts an IC structure 100D, FIG. 5 depicts an IC structure 100E, FIG. 6 depicts an IC structure 100F, FIG. 7 depicts an IC structure 100G, FIG. 8 depicts an IC structure 100H, FIG. 9 depicts an IC structure 100I, FIG. 10 depicts an IC structure 100J, FIG. 11 depicts an IC structure 100K, FIG. 12 depicts an IC structure 100L, FIG. 13 depicts an IC structure 100M, FIG. 14 depicts an IC structure 100N, FIG. 15 depicts an IC structure 100O, and FIG. 16 depicts an IC structure 100P. FIGS. 17A and 17B depict a portion of the stacked capacitor structure of IC structure 100A of FIG. 1 according to various aspects of the present disclosure. FIGS. 18A and 18B depict a portion of the stacked capacitor structure of IC structure 100B of FIG. 2 according to various aspects of the present disclosure. FIGS. 19A–19F and 20A-20D depict various configurations of stacked capacitor structures that may be implemented in IC structures 100A–100O according to various aspects of the present disclosure. FIG. 21 depicts a configuration of a stacked capacitor structure that may be implemented in IC structures 100A–100O according to various aspects of the present disclosure. Since IC structures 100A–100O are similar in many respects, similar features of IC structures 100A–100O are identified by the same reference numerals for clarity and simplicity. FIGS. 1–16, 17A, 17B, 18A, 18B, 19A-19F, 20A-20D and 21, have been simplified for the sake of clarity to better understand the inventive concepts of the present disclosure. Additional features may be added in IC structures 100A–100O, and some of the features described below may be replaced, modified, or eliminated in other embodiments of IC structures 100A–100O.

Referring to FIG. 1, IC structure 100A includes a device substrate 102. Device substrate 102 includes a substrate (e.g., a semiconductor substrate, such as a silicon substrate) having circuitry fabricated on and/or over a first side thereof (e.g., a frontside thereof), for example, by front end-of-line (FEOL) processing. For example, device substrate 102 (also referred to as an IC substrate) includes various device components/features, such as a semiconductor substrate, doped wells (e.g., n-wells and/or p-wells), isolation features (e.g., shallow trench isolation (STI) structures and/or other suitable isolation structures), gates (e.g., a gate stack, such as a gate electrode and a gate dielectric), gate spacers along sidewalls of the gates, source/drains (e.g., epitaxial source/drains), other suitable device components and/or device features, or combinations thereof. The various device components/features may combine to form circuitry 105. In some embodiments, circuitry 105 includes one or more planar transistors, where a channel of a planar transistor is formed in a semiconductor substrate between respective source/drains and a respective gate is disposed on the channel (e.g., on a portion of the semiconductor substrate in which the channel is formed). In some embodiments, circuitry 105 includes one or more non-planar transistors having channels formed in a respective semiconductor fin(s) extending from a semiconductor substrate and between respective source/drains on/in the semiconductor fin(s), where a respective gate is disposed on and wraps a channel of the semiconductor fin(s) (i.e., the non-planar transistors are fin-like field effect transistors (FinFETs)). In some embodiments, circuitry 105 includes one or more non-planar transistors having channels formed in semiconductor layers disposed above a semiconductor substrate and extending between respective source/drains, where a respective gate at least partially surrounds respective channels (i.e., the non-planar transistors may be gate-all-around (GAA) transistors). The transistors of device substrate 102 and/or circuitry 105 may be configured as planar transistors and/or non-planar transistors depending on design requirements. In some embodiments device substrate 102 and/or circuitry 105 include stacked transistors, such as complementary field effect transistors (CFETs) and/or other stacked transistors.

Device substrate 102 and/or circuitry 105 may include various passive microelectronic devices and/or active microelectronic devices, such as resistors, capacitors, inductors, diodes, p-type FETs (PFETs), n-type FETs (NFETs), metal-oxide semiconductor (MOS) FETs (MOSFETs), complementary MOS (CMOS) transistors, bipolar junction transistors (BJTs), laterally diffused MOS (LDMOS) transistors, high voltage transistors, high frequency transistors, other suitable devices and/or components, or combinations thereof. The various microelectronic devices may be configured to provide functionally distinct regions of an IC, such as a logic region (i.e., a core region), a memory region, an analog region, a peripheral region (e.g., an I/O region), a dummy region, other suitable region, or combinations thereof. The logic region may be configured with standard cells, each of which may provide a logic device and/or a logic function, such as an inverter, an AND gate, a NAND gate, an OR gate, a NOR gate, a NOT gate, an XOR gate, an XNOR gate, other suitable logic device, or combinations thereof. The memory region may be configured with memory cells, each of which may provide a storage device and/or storage function, such as flash memory, non-volatile random-access memory (NVRAM), SRAM, dynamic random-access memory (DRAM), other volatile memory, other non-volatile memory, other suitable memory, or combinations thereof. In some embodiments, memory cells and/or logic cells include transistors and interconnect structures that combine to provide, respectively, storage devices/functions and logic devices/functions.

IC structure 100A may further include a multilayer interconnect (MLI) structure 110 fabricated on and/or over device substrate 102, for example, by middle-of-line (MOL) processing and/or back end-of-line (BEOL) processing. MLI structure 110 may be a frontside MLI structure (such as depicted) or a backside MLI structure depending on configuration of IC structure 100A. MLI structure 110 includes a combination of insulation layers (e.g., dielectric layers), which are collectively depicted as an insulation layer 112, and electrically conductive layers (e.g., patterned metal layers, each of which may be a group of metal lines, metal vias, metal contacts, or combinations thereof arranged in a desired pattern) that combine to form interconnect (routing) structures. The interconnect structures may provide vertically routing structures, such as metal contacts and/or metal vias, between horizontally routing structures, such as metal line 114A and metal line 114B, in different layers/levels/planes of MLI structure 110. The electrically conductive layers of MLI structure 110 may provide electrical connectivity to circuitry 105 and/or connect one or more devices and/or circuits of device substrate 102. In some embodiments, the interconnect structures routes electrical signals between devices (e.g., circuitry 105) and/or components of device substrate 102, devices and/or components disposed in MLI structure 110, external devices and/or components, or combinations thereof. In some embodiments, the interconnect structures distribute electrical signals (e.g., clock signals, voltage signals, ground signals, etc.) to the devices and/or the device components of device substrate 102, MLI structure 110, external devices and/or components, or combinations thereof.

The patterned metal layers are distributed in multiple levels. For example, MLI structure 110 may include a device-level contact layer and/or via layer (which may collectively be referred to as a via zero layer (V0 level)), a metal zero layer (M0 level), a via one layer (V1 level), a metal one layer (M1 level), a via two layer (V2 level), a metal two layer (M2 level), and so on to a via (X-1) layer (V(X-1) level), a metal (X-1) layer (M(X-1) level), a via X layer (VX level), and a metal X layer (MX level), where X is an integer (e.g., from 2 to 10). Each level of MLI structure 110 may include respective vertical routing structures (e.g., metal vias) and/or horizontal routing structures (e.g., metal lines) disposed in a respective portion of insulation layer 112. Metal lines of M0 level, M1 level, M2 level, . . . M(X-1) level, and MX level may be referred to as M0 lines, M1 lines, M2 lines, . . . M(X-1) lines, and MX lines, respectively. Metal vias of V0 level, V1 level, V2 level, . . . V(X-1) level, and VX level may be referred to as V0 vias, V1 vias, V2 vias, . . . V(X-1) vias, and VX vias, respectively. In some embodiments, a respective metal via may connect an underlying metal line (e.g., a respective M1 line) and an overlying metal line (e.g., a respective M2 line), an underlying device-level contact (e.g., a source/drain contact) and an overlying metal line (e.g., a respective M0 line), or an underlying device feature (e.g., a gate and/or a source/drain) and an overlying metal line (e.g., a respective M0 line). In some embodiments, such as depicted, metal line 114A and metal line 114B belong to a top metal layer of MLI structure 110 (e.g., MX level thereof). In some embodiments, metal line thickness may increase as distance from device substrate 102 increases. For example, a thickness of a metal line of a bottommost one of the patterned metal layers (e.g., at and/or proximate device substrate level) may be less than a thickness of a metal line of a patterned metal layer (e.g., a topmost one) above the bottommost one the patterned metal layers. In some embodiments, metal lines of a patterned metal layer may extend lengthwise along different directions. In some embodiments, metal lines of a patterned metal layer may extend lengthwise along a same direction. In some embodiments, a patterned metal layer may include groups of metal lines having different pitches. In some embodiments, at least two of the patterned metal layers have different pitches. In some embodiments, a pitch of the metal lines of a patterned metal layer may increase as distance from device substrate 102 increases.

In some embodiments, insulation layer 112 has a multilayer structure. For example, insulation layer 112 includes at least one ILD layer, at least one CESL disposed between respective ILD layers, and at least one CESL disposed between a respective ILD layer and device substrate 102. In some embodiments, a composition of the CESL is different from a composition of the ILD layer. For example, where the ILD layer includes a low-k dielectric material that includes silicon and oxygen, the CESL may include silicon and nitrogen (e.g., silicon nitride, silicon oxynitride, silicon carbonitride, or combinations thereof) or other suitable dielectric material (e.g., metal nitride). The ILD layer may have a multilayer structure having multiple dielectric materials, and/or the CESL may have a multilayer structure having multiple dielectric materials. In some embodiments, insulation layer 112 includes ILD layers interleaved by CESLs, and each level of MLI structure 110 may include a respective ILD layer, a respective CESL, and a respective patterned metal layer disposed in the respective ILD layer and the respective CESL. Metal lines of the respective patterned metal layer may be spaced apart from one another by the respective ILD layer and/or the respective CESL. In some embodiments, ILD layer thickness may increase as distance from device substrate 102 increases. For example, a thickness of a bottommost one of the ILD layers (e.g., at and/or proximate device substrate level) may be less than a thickness of an ILD layer (e.g., a topmost one of the ILD layers) above the bottommost one of the ILD layers. In some embodiments, a dielectric constant of at least one of the CESLs is greater than a dielectric constant of at least one of the ILD layers. In some embodiments, an etch resistance of at least one of the CESLs to a halogen-containing gas is greater than an etch resistance of at least one of the ILD layers to the halogen-containing gas.

IC structure 100A includes a passivation structure 120 fabricated on and/or over MLI structure 110, for example, by BEOL processing. Passivation structure 120 may include multiple passivation layers, such as a passivation layer 122 (PASS1), a passivation layer 124 (PASS2), and a passivation layer 126. Passivation layer 122, passivation layer 124, passivation layer 126, or combinations thereof may have a multilayer structure and may include multiple passivation sublayers. For example, passivation layer 122 (PASS1) may include a first passivation sublayer 122-1 (PASS1-1), a second passivation sublayer 122-2 (PASS1-2), a third passivation sublayer 122-3 (PASS1-3), and a fourth passivation sublayer 122-4 (PASS1-4). Passivation layer 122 (including passivation sublayers 122-1–122-4), passivation layer 124, and passivation layer 126 include silicon nitride, silicon oxide (e.g., undoped silica glass (USG)), silicon oxynitride, silicon carbonitride, polyimide, polybenzoxadole, other suitable passivation material(s), or combinations thereof. In some embodiments, passivation layer 124 has a multilayer structure, such as a polyimide layer disposed over a dielectric layer. The dielectric layer may also have a multilayer structure (e.g., a silicon nitride layer over a USG layer). The present disclosure contemplates passivation layers/sublayers including other types of passivation materials.

IC structure 100A further includes a capacitor structure 130 disposed in passivation structure 120. Capacitor structure 130 may be fabricated by BEOL processing, and capacitor structure 130 includes a combination of conductor layers (e.g., metal layers) and insulator layers (e.g., dielectric layers). For example, capacitor structure 130 includes conductor layers 132, conductor layers 134, conductor layers 136, conductor layers 138, insulator layers 140, and insulator layers 142. Conductor layers 132, conductor layers 134, conductor layers 136, and conductor layers 138 include electrically conductive material, such as titanium nitride, tungsten, titanium aluminum, copper, or combinations thereof, though the present disclosure contemplates conductor layers including other types of electrically conductive material. Insulator layers 140 and insulator layers 142 include a dielectric material, such as a high-k dielectric material, which is a dielectric material having a dielectric constant greater than a dielectric constant of silicon oxide. The high-k dielectric material may include HfO₂, ZrO₂, ZrOₓN_{y}, HfOₓN_{y}, HfSiₓO_{y}, ZrSiₓO_{y}, HfSiₓO_{y}N_{z}, ZrSiₓO_{y}N_{z}, Al₂O₃, TiO₂, Ta₂O₅, La₂O₃, CeO₂, Bi₄Si₂O₁₂, WO₃, Y₂O₃, LaAlO₃, PbTiO₃, BaTiO₃, SrTiO₃, PbZrO₃, other high-k dielectric materials or combinations thereof. In some embodiments, insulator layers 140 and/or insulator layers 142 have a multilayer structure. For example, insulator layers 140 and/or insulator layers 142 may have a tri-layer structure including, from bottom to top, a first zirconium oxide (e.g., ZrO₂) layer, an aluminum oxide (Al₂O₃) layer, and a second zirconium oxide (ZrO₂) layer. In such embodiments, the insulator layers may be referred to as ZAZ layers. The present disclosure contemplates insulator layers having multilayer structures formed from other high-k dielectric materials.

In some embodiments, such as depicted, capacitor structure 130 includes a capacitor stack 150A (e.g., embedded in passivation sublayer 122-1 and passivation sublayer 122-2) and a capacitor stack 150B (e.g., embedded in passivation sublayer 122-3 and passivation sublayer 122-4). Capacitor stack 150A and capacitor stack 150B include four conductor layers – a conductor layer 132 (ELECTRODE-1), a conductor layer 134 (ELECTRODE-2), a conductor layer 136 (ELECTRODE-3), and a conductor layer 138 (ELECTRODE-4) – and two insulator layers – an insulator layer 140 (HK-1) and an insulator layer 142 (HK-2). The four conductor layers and the two insulator layers are configured and arranged to provide trench MIM stacks 152 and pillar MIM stacks 154. Pillar MIM stacks 154 are disposed over trench MIM stacks 152. In some embodiments, a MIM unit 156 (also referred to as a MIM structure and/or a capacitor unit) includes a respective pillar MIM stack 154 and a respective trench MIM stack 152, and the respective pillar MIM stack 154 overlaps the respective trench MIM stack 152. The respective trench MIM stack 152 and the respective pillar MIM stack 154 may form two different capacitors, and in some embodiments, may be connected into one capacitor. In some embodiments, MIM units 156 include pillar MIM stacks 154 that are aligned with (e.g., center aligned) trench MIM stacks 152. In some embodiments, MIM units 156 include pillar MIM stacks 154 that are staggered relative to (e.g., shifted left or right of center of) trench MIM stacks 152. In the depicted embodiment, two MIM units 156 are provided by capacitor stack 150A, two MIM units 156 are provided by capacitor stack 150B, and MIM units 156 of capacitor stack 150B are aligned with (e.g., center aligned) with MIM units 156 of capacitor stack 150A. In some embodiments, MIM units 156 of capacitor stack 150B are staggered relative to (e.g., shifted left or right of center of) MIM units 156 of capacitor stack 150A.

As the names suggest, trench MIM stacks 152 are MIM stacks inserted into trenches (e.g., during fabrication thereof) and/or protruding downwardly (e.g., towards device substrate 102), and pillar MIM stacks 154 are MIM stacks folded into pillar-like and/or fin-like structures (e.g., during fabrication thereof) and/or protruding upwardly (e.g., away from device substrate 102). Given the different profile configurations of trench MIM stacks 152 and pillar MIM stacks 154 (e.g., different protrusion directions), MIM units 156 may be referred to as hybrid MIM stacks. Trench MIM stacks 152 include an insulator layer (e.g., a respective insulator layer 140) sandwiched between two electrodes (e.g., a respective conductor layer 132 and a respective conductor layer 134, which may be referred to as a bottom electrode and a top electrode, respectively, of a trench MIM stack), and pillar MIM stacks 154 include an insulator layer (e.g., a respective insulator layer 142) sandwiched between two electrodes (e.g., a respective conductor layer 136 and a respective conductor layer 138, which may be referred to as a bottom electrode and a top electrode, respectively, of a pillar MIM stack). In some embodiments, such as depicted, conductor layer 136 (ELECTRODE-3) is disposed directly on and abuts conductor layer 134 (ELECTRODE-2). In such embodiments, bottom electrodes of pillar MIM stacks 154 and top electrodes of trench MIM stacks 152 share an interface.

Various dimensions of MIM units 156 may be configured and designed in consideration of packing density, an area, a capacitance, uniformity, and processing quality of capacitor structure 130. Referring to FIG. 17A, a given MIM unit 156 has a height H (e.g., along a z-direction between a top of its pillar MIM stack 154 and a bottom of its trench MIM stack 152) and a width W (e.g., along an x-direction or a y-direction). MIM units 156 may be arranged according to a periodic dimension, such as a pitch P (e.g., along the x-direction and/or the y-direction), and a spacing S (e.g., along the x-direction and/or the y-direction) is between trench MIM stacks 152 and/or pillar MIM stacks 154 of adjacent MIM units 156. In the depicted embodiment, trench MIM stack 152 and pillar MIM stack 154 have the same width (e.g. width W), though the present disclosure contemplates trench MIM stack 152 and pillar MIM stack 154 having different widths, in some embodiments. Trench MIM stack 152 has a height Ht (e.g., along the z-direction), which corresponds with a dimension of a downward protrusion of trench MIM stack 152 (i.e., a non-planar portion of trench MIM stack 152 that protrudes from a planar portion of trench MIM stack 152), and pillar MIM stack 154 has a height Hp (e.g., along the z-direction), which corresponds with a dimension of an upward protrusion of pillar MIM stack 154 (i.e., a non-planar portion of pillar MIM stack 154 that protrudes from a planar portion of pillar MIM stack 154). In some embodiments, MIM unit 156 may be configured with one or more of the following: height H of about 0.4 µm to about 1.6 µm; pitch P of about 0.2 µm and 0.8 µm; width W of about 0.1 µm to about 0.4 µm; spacing S of about 0.1 µm to about 0.4 µm; height Ht of about 0.2 µm to about 0.8 µm; and height Hp of about 0.2 µm to about 0.8 µm.

Trench MIM stack 152 and pillar MIM stack 154 may be configured to have various shapes. For example, trench MIM stack 152 and pillar MIM stack 154 may have rectangular or square cross-sectional profiles, such as depicted in FIG. 17A, or trapezoidal profiles, such as depicted in FIG. 1. Trench MIM stack 152 and pillar MIM stack 154 may have substantially vertical sidewalls, such as depicted in FIG. 17A, or tapered sidewalls, such as depicted in FIG. 1. An angle σt is between sidewalls of trench MIM stack 152 and an xy-plane (i.e., a plane defined by the x-direction and the y-direction)(in the depicted embodiment, provided by a bottom of trench MIM stack 152), and an angle σp is between sidewalls of pillar MIM stack 154 and an xy-plane (in the depicted embodiment, provided by a top of pillar MIM stack 154). Further, conductor layer 132 has a thickness t1, conductor layer 134 has a thickness t2, and conductor layer 138 has a thickness t3, and thickness t1, thickness t2, and thickness t3 may be the same or different depending on design specifications. In some embodiments, MIM unit 156 may be configured with one or more of the following: angle σt of about 75º to about 90º; angle σp of about 90º to about 105º; thickness t1 of about 0.02 µm to about 0.07 µm; thickness t2 of about 0.02 µm to about 0.07 µm; and thickness t3 of about 0.02 µm to about 0.07 µm.

Referring to FIGS. 19A–19F, MIM units 156 of capacitor structure 130 may be arranged into a MIM array (also referred to as a capacitor array). For example, in a top view, capacitor structure 130 may include (1) a MIM array 156-1 that includes square-shaped MIM units 156 arranged into rows (e.g., three) and columns (e.g., three) (FIG. 19A); (2) a MIM array 156-2 that includes rectangular-shaped MIM units 156 arranged into rows (e.g., three) and columns (e.g., two) (FIG. 19B); and/or (3) a MIM array 156-3 that includes circular-shaped MIM units 156 (or oval-shaped MIM units 156) arranged into rows (e.g., three) and columns (e.g., three) (FIG. 19C). In the embodiments of FIGS. 19A–19C, MIM units 156 may be aligned along the x-direction and the y-direction. In some embodiments, MIM units 156 may be staggered along the x-direction and/or the y-direction. For example, in a top view, capacitor structure 130 may include (1) a MIM array 156-4 similar to MIM array 156-1, except the rows of square-shaped MIM units 156 (e.g., three) may be staggered relative to one another, such that upper sides and/or lower sides of the square-shaped MIM units 156 abut more than one square-shaped MIM unit 156 (FIG. 19D); (2) a MIM array 156-5 similar to MIM array 156-2, except the rows of rectangular-shaped MIM units 156 (e.g., three) may be staggered relative to one another, such that upper sides and/or lower sides of the rectangular-shaped MIM units 156 abut more than one rectangular-shaped MIM unit 156 (FIG. 19E); and/or (3) a MIM array 156-6 similar to MIM array 156-3, except the rows of circle-shaped MIM units 156 (e.g., three) may be staggered relative to one another, such that upper sides and/or lower sides of the circle-shaped MIM units 156 abut more than one circle-shaped MIM unit 156 (FIG. 17F). In the MIM arrays depicted in FIGS. 19A–19F, MIM units 156 include a respective trench MIM stack 152 and a respective pillar MIM stack 154, and dimensions of trench MIM stacks 152 (e.g., widths thereof) are greater than dimensions of pillar MIM stacks 154 (e.g., widths thereof). In such embodiments, widths of trench MIM stacks 152 may be width W, and widths of pillar MIM stacks 154 may be less than width W. In some embodiments, the dimensions of trench MIM stacks 152 are less than the dimensions of pillar MIM stacks 154. In some embodiments, the dimensions of trench MIM stacks 152 are the same as the dimensions of pillar MIM stacks 154.

Referring to FIGS. 20A–20D, MIM units 156 of capacitor structure 130 (and/or of MIM arrays thereof) may include various configurations of trench MIM stacks 152 and pillar MIM stacks 154. In some embodiments, in a top view, capacitor structure 130 may include a MIM array 156-7 (FIG. 20A) that includes a row of rectangular-shaped MIM units 156, each of which may include a rectangular-shaped (and/or slot-shaped) trench MIM stack 152 having square-shaped (or other shaped, such as circular-shaped) pillar MIM stacks 154 disposed thereon (e.g., three). In some embodiments, the rectangular-shaped MIM units 156 and the rectangular-shaped trench MIM stacks 152 extend lengthwise along the same direction (e.g., the y-direction) and the square-shaped pillar MIM stacks 154 may be arranged into a column along the lengthwise direction and/or aligned (e.g., center aligned) along the lengthwise direction. In some embodiments, in a top view, capacitor structure 130 may include a MIM array 156-8 (FIG. 20B) that is similar to MIM array 156-7, except MIM array 156-8 includes rectangular-shaped pillar MIM stacks 154, instead of square-shaped pillar MIM stacks 154, disposed over the rectangular-shaped trench MIM stacks 152. The rectangular-shaped pillar MIM stacks 154 may extend lengthwise along the same lengthwise direction as trench MIM stacks 152.

In some embodiments, in a top view, capacitor structure 130 may include a MIM array 156-9 (FIG. 20C) that includes rows (e.g., three) of rectangular-shaped MIM units 156, each of which may include square-shaped (or other shaped, such as circular-shaped) trench MIM stacks 152 and a rectangular-shaped (and/or slot-shaped) pillar MIM stack 154 disposed thereon. In some embodiments, the rectangular-shaped MIM units 156 and the rectangular-shaped pillar MIM stack 154 extend lengthwise along the same direction (e.g., the x-direction) and the square-shaped trench MIM stacks 152 may be arranged into a row along the lengthwise direction and/or aligned (e.g., center aligned) along the lengthwise direction. In the embodiments of FIGS. 20A–20C, trench MIM stacks 152 and pillar MIM stacks 154 are confined within and form a portion of a single, respective MIM unit 156. In some embodiments, trench MIM stacks 152 and/or pillar MIM stacks 154 may belong to, form a portion of, and/or span more than one MIM unit 156. For example, in some embodiments, in a top view, capacitor structure 130 may include a MIM array 156-10 (FIG. 20D) that is similar to MIM array 156-8, except the rectangular-shaped pillar MIM stacks 154 of MIM array 156-10 extend lengthwise along a direction different from, instead of the same as, the lengthwise direction of trench MIM stacks 152. In such embodiments, the rectangular-shaped pillar MIM stacks 154 form a portion of and/or span more than one MIM unit 156 (e.g., three), and the rectangular-shaped pillar MIM stacks 154 are not confined within a boundary of a single, respective MIM unit 156.

Returning to FIG. 1, IC structure 100A includes metal vias, such as a metal via 160A and a metal via 160B, disposed in passivation layer 122 and redistribution lines (RDLs), such as an RDL 162A and an RDL 162B, disposed in passivation layer 124. Metal via 160A and metal via 160B extend from RDL 162A and RDL 162B, respectively, through passivation layer 122 to metal line 114A and metal line 114B, respectively. Metal via 160A and metal via 160B also extend through capacitor structure 130 (e.g., through conductor layers 138, conductor layers 136, conductor layers 134, conductor layers 132, insulator layers 142, and insulator layers 140 thereof). Metal via 160A, metal via 160B, RDL 162A, and RDL 162B include electrically conductive material, such as aluminum, copper, titanium, tantalum, tungsten, ruthenium, molybdenum, cobalt, iridium, palladium, platinum, nickel, tin, gold, silver, other metal, alloys thereof (e.g., TiN, TaN, TaC, TaCN, TiAl, TiAlN, etc.), silicides thereof (e.g., NiSi, CoSi, CuSi, TaSiN, etc.), or combinations thereof. In some embodiments, metal via 160A and metal via 160B may be Al vias, AlCu vias, or Cu vias. In some embodiments, RDL line 162A and/or RDL line 162B may be Al lines, AlCu lines, or Cu lines. In some embodiments, metal via 160A, metal via 160B, RDL 162A, RDL 162B, or combinations thereof have a multilayer structure. The multilayer structure may include a metal plug (e.g., an Al plug, an AlCu plug, or a Cu plug) over a barrier/seed layer that facilitates adhesion of the metal plug and/or prevents diffusion of metal from the metal plug into passivation structure 120. Other types of electrically conductive material for metal via 160A, metal via 160B, RDL 162A, and RDL 162B are contemplated.

Metal via 160A is connected to conductor layers 132 and conductor layers 138, metal via 160B is connected to conductor layers 134, and metal via 160B may be connected to conductor layers 136 through conductor layers 134. Referring to FIGS. 1, 17A, and 17B, electrical access to the bottom electrodes of trench MIM stacks 152 and the top electrodes of pillar MIM stacks 154 may thus be provided by RDL line 162A through metal via 160A, which is electrically coupled/connected to metal line 114A, and electrical access to the top electrodes of trench MIM stacks 152 and the bottom electrodes of pillar MIM stacks 154 may thus be provided by RDL line 162B through metal via 160B, which is electrically coupled/connected to metal line 114B. As such, metal via 160A (and corresponding RDL line 162A) and metal via 160B (and corresponding RDL line 162B) may be used to control electrical operation of capacitor structure 130. For example, different electrical voltage potentials may be applied to RDL line 162A and RDL line 162B (e.g., through connectors 164), which is applied to electrodes of trench MIM stacks 152 and pillar MIM stacks 154 via metal via 160A and metal via 160B. In some embodiments, a positive voltage is applied (e.g., via metal via 160A) to the bottom electrodes of trench MIM stacks 152 and the top electrodes of pillar MIM stacks 154, and a negative voltage is applied (e.g., via metal via 160B) to the top electrodes of trench MIM stack 152 and the bottom electrodes of pillar MIM stacks 154. In some embodiments, a negative voltage is applied to the bottom electrodes of trench MIM stacks 152 and the top electrodes of pillar MIM stack 154, and a positive voltage is applied to the top electrodes of trench MIM stacks 152 and the bottom electrodes of pillar MIM stacks 154.

IC structure 100A may further include a bump structure (which may also be referred to as a bonding structure, in some embodiments). For example, a bump structure may be formed over passivation structure 120, and the bump structure may electrically couple IC structure 100A, including capacitor structure 130, to a power supply. The bump structure may include connectors 164 disposed over and/or in passivation layer 124. Connectors 164 are connected to a respective RDL line(s), such as RDL line 162A or RDL line 162B. In some embodiments, RDL line 162A and RDL line 162B are or form a portion of a redistribution layer (RDL) structure, which may redistribute connectors 164 (e.g., bonding pads) as needed. Such redistribution enables electrical connections/coupling from an edge to a center of an IC chip (e.g., which may include IC structure 100), which may facilitate flip chip bonding or other suitable packaging technologies to integrate the IC chip with a packaging component, such as a printed circuit board. The RDL structure may thus include various RDL lines and RDL vias embedded in passivation structure 120 (e.g., in passivation layer 124 thereof) and in a configuration that electrically couples/connects top metal lines of MLI structure 110 (e.g., metal line 114A and metal line 114B) to respective connectors 164 according to a given designed IC.

Each connector 164 may include a respective under-bump metallization (UBM) structure 166 and a respective solder bump/cap 168. UBM structures 166 and solder bumps 168 include electrically conductive materials, such as those described herein. In some embodiments, UBM structures 166 include multiple layers of different metals, such as an adhesion layer (e.g., Ti, Cr, Al, other metal, or combinations thereof), a diffusion barrier layer (e.g., CrCu alloy and/or other suitable metal(s)), a solderable layer, an oxidation barrier layer (e.g., Au and/or other suitable metal(s)), or combinations thereof. In some embodiments, UBM structures 166 may be configured as UBM pillar structures including, for example, metal pillars (e.g., Cu pillars) disposed over one or more UBM layers. In some embodiments, connectors 164 may be formed as controlled-collapse chip connection bumps (C4 bumps), ball grid array (BGA) bumps, land grid array (LGA) bumps, pin grid array (PGA) bumps, microbumps, or the like.

For a given area, capacitor structure 130, which includes trench MIM stacks 152 and pillar MIM stacks 154, provides significantly increased capacitance compared to a capacitor structure formed of planar MIM stacks. For example, since a capacitor’s capacitance is directly correlated with a surface area between its insulator material and its electrodes between which the insulator material is located, capacitance increases are typically achieved by enlarging lateral dimensions of planar MIM stacks to increase their capacitance, which may undesirably consume valuable IC chip real estate. In contrast, the disclosed capacitor structures, such as capacitor structure 130, are configured with non-planar portions (i.e., trench MIM stacks 152 and pillar MIM stacks 154) that provide extra surface area between their insulator materials and their electrodes, such that the capacitor structures of the present disclosure can achieve greater capacitance without requiring extra chip area. Further, because the extra capacitance gained by the disclosed capacitor structures is fairly consistent and easily calculated, the capacitance may be unitized to provide IC design flexibility. For example, if a certain IC application desires a certain amount of capacitance, a determination may be made beforehand as to how many MIM units (e.g., MIM units 156) may be needed to achieve such a capacitance.

However, though the disclosed capacitor structures, such as capacitor structure 130, may increase capacitance without increasing occupied area (e.g., occupied die/chip area), the present disclosure further recognizes that stacking MIM stacks may result in longer and/or slower overall transmission paths. In other words, electrical signals may take longer to travel to/from and/or through capacitor structure 130, which may degrade operating speed thereof and/or of IC structure 100A. To offset reductions in electrical signal speed that may arise from the longer/slower transmission paths, additional conductor layers (e.g., metal plates) are inserted into capacitor structure 130 to provide additional (e.g., parallel) connections to top electrodes and/or bottom electrodes of the MIM stacks (e.g., trench MIM stacks 152 and/or pillar MIM stacks 154) thereof. The extra connections to the top electrodes and/or the bottom electrodes of the MIM stacks provide additional paths for electrical signals to flow to/from the MIM stacks, which reduces series resistance (Rₛ) of capacitor structure 130. Capacitor structure 130 may thus achieve faster signal transmission, thereby improving overall device performance and/or speed, without requiring significant redesign. Further, processing associated with incorporating additional metal plates/connections into capacitor structures 130 is relatively easy and cheap to integrate into existing capacitor fabrication processes and/or packaging processes. Yet another advantage offered by the disclosed capacitor structures, such as capacitor structure 130, is circuit design flexibility. For example, customers can decide which layer(s) and/or level(s) of their capacitor structures to insert extra metal plates based on their own circuit designs.

In some embodiments, such as depicted, capacitor structure 130 includes extra conductor layers, such as an extra bottom conductor layer 170B (which may be referred to as extra bottom plate (EBP) 170B hereafter), an extra middle conductor layer 170M (which may be referred to as an extra middle plate (EMP) 170M hereafter), and an extra top conductor layer 170T (which may be referred to as an extra top plate (ETP) 170T hereafter). EBP 170B, EMP 170M, and ETP 170T include electrically conductive material, such as titanium nitride, tungsten, titanium aluminum, copper, or combinations thereof, though the present disclosure contemplates EBPs including other types of electrically conductive material. In some embodiments, EBP 170B, EMP 170M, and ETP 170T are titanium nitride layers, tungsten layers, or copper layers. In some embodiments, EBP 170B, EMP 170M, and ETP 170T, or combinations thereof, include the same electrically conductive materials and/or have the same configurations. In some embodiments, EBP 170B, EMP 170M, and ETP 170T, or combinations thereof, include different electrically conductive materials and/or have different configurations.

EBP 170B forms a bottom of capacitor structure 130, and EBP 170B may be disposed and/or formed in passivation sublayer 122-1. Bottom electrodes of trench MIM stacks 152 (e.g., conductor layer 132) of capacitor stack 150A are formed on EBP 170B, and EBP 170B may extend over top metal lines of MLI structure 110 (e.g., metal line 114A and metal line 114B). EBP 170B thus abuts and shares an interface with bottom electrodes of trench MIM stacks 152 of capacitor stack 150A and top metal lines of MLI structure 110. EBP 170B further extends to metal via 160A, such that metal via 160A is further electrically coupled/connected to bottom electrodes of trench MIM stacks 152 of capacitor stack 150A through EBP 170B. With such configuration, capacitor structure 130 provides two electrical connections to the bottom electrodes of trench MIM stacks 152 of capacitor stack 150A – a first electrical connection directly to the bottom electrodes of trench MIM stacks 152 of capacitor stack 150A (e.g., via metal via 160A) and a second electrical connection through EBP 170B (e.g., via metal via 160A) to the bottom electrodes of trench MIM stacks 152 of capacitor stack 150A. EBP 170B (e.g., an extra connection) may thus reduce resistance associated with delivering current to bottom electrodes of trench MIM stacks 152 of capacitor stack 150A. In some embodiments, EBP 170B and bottom electrodes of trench MIM stacks 152 of capacitor stack 150A include the same materials. For example, EBP 170B and conductor layers 132 are both titanium nitride layers, tungsten layers, or copper layers. In some embodiments, EBP 170B and bottom electrodes of trench MIM stacks 152 of capacitor stack 150A include different materials.

EMP 170M forms a middle of capacitor structure 130, and EMP 170M may be disposed and/or formed in passivation layer 126 (and/or passivation sublayer 122-3 and/or passivation sublayer 122-2, in some embodiments). EMP 170M is formed on top electrodes of pillar MIM stacks 154 (e.g., conductor layer 138) of capacitor stack 150A, and bottom electrodes of trench MIM stacks 152 (e.g., conductor layer 132) of capacitor stack 150B are formed on EMP 170M. EMP 170M thus abuts and shares an interface with top electrodes of pillar MIM stacks 154 of capacitor stack 150A and bottom electrodes of trench MIM stacks 152 of capacitor stack 150B. EMP 170M further extends to metal via 160A, such that metal via 160A is further electrically coupled/connected to top electrodes of pillar MIM stacks 154 of capacitor stack 150A and bottom electrodes of trench MIM stacks 152 of capacitor stack 150B through EMP 170M. With such configuration, capacitor structure 130 provides two electrical connections to the top electrodes of pillar MIM stacks 154 of capacitor stack 150A and bottom electrodes of trench MIM stacks 152 of capacitor stack 150B – a first electrical connection directly to the top electrodes of pillar MIM stacks 154 of capacitor stack 150A and the bottom electrodes of trench MIM stacks 152 of capacitor stack 150B (e.g., via metal via 160A) and a second electrical connection through EMP 170M (e.g., via metal via 160A) to the top electrodes of pillar MIM stacks 154 of capacitor stack 150A and the bottom electrodes of trench MIM stacks 152 of capacitor stack 150B. EMP 170M (e.g., an extra connection) may thus reduce resistance associated with delivering current to the top electrodes of pillar MIM stacks 154 of capacitor stack 150A and the bottom electrodes of trench MIM stacks 152 of capacitor stack 150B. In some embodiments, EMP 170M includes the same materials as top electrodes of pillar MIM stacks 154 of capacitor stack 150A and/or bottom electrodes of trench MIM stacks 152 of capacitor stack 150B. In some embodiments, EMP 170M includes different materials than top electrodes of pillar MIM stacks 154 of capacitor stack 150A and/or different materials than electrodes of trench MIM stacks 152 of capacitor stack 150B.

ETP 170T forms a top of capacitor structure 130, and ETP 170T may be disposed and/or formed in passivation sublayer 122-4. ETP 170T is formed on top electrodes of pillar MIM stacks 154 (e.g., conductor layer 138) of capacitor stack 150B. ETP 170T thus abuts and shares an interface with top electrodes of pillar MIM stacks 154 of capacitor stack 150B. ETP 170T further extends to metal via 160A, such that metal via 160A is further electrically coupled/connected to top electrodes of pillar MIM stacks 154 of capacitor stack 150B through ETP 170T. With such configuration, capacitor structure 130 provides two electrical connections to the top electrodes of pillar MIM stacks 154 of capacitor stack 150B – a first electrical connection directly to the top electrodes of pillar MIM stacks 154 of capacitor stack 150B (e.g., via metal via 160A) and a second electrical connection through ETP 170T (e.g., via metal via 160A) to the top electrodes of pillar MIM stacks 154 of capacitor stack 150B. ETP 170T (e.g., an extra connection) may thus reduce resistance associated with delivering current the top electrodes of pillar MIM stacks 154 of capacitor stack 150B. In some embodiments, ETP 170T and top electrodes of pillar MIM stacks 154 of capacitor stack 150B include the same materials. For example, ETP 170T and conductor layers 133 are both titanium nitride layers, tungsten layers, or copper layers. In some embodiments, ETP 170T and top electrodes of pillar MIM stacks 154 of capacitor stack 150B include different materials.

It is further noted that, in contrast to trench MIM stacks 152 (which are three-dimensional structures that include non-planar portions (e.g., downward protrusions relative to device substrate 102)) and pillar MIM stacks 154 (which are three-dimensional structures that include non-planar portions (e.g., upward protrusions relative to device substrate 102)), EBP 170B and EMP 170M are planar structures, whereas ETP 170T conforms to a shape of pillar MIM stacks 154, such that ETP 170T has planar portions and non-planar portions (e.g., upwardly protruding portions relative to device substrate 102). Because ETP 170T conforms to the shape of pillar MIM stacks 154, ETP 170T may partially fill a gap 175 (and/or spacing S) between adjacent pillar MIM stacks 154 (e.g., between conductor layers 138 thereof), and passivation layer 122-4 may fill a remainder of gap 175. In some embodiments, fabrication of capacitor structure 130 may be configured to provide ETP 170T as a planar structure (as described further below). In some embodiments, fabrication of capacitor structure 130 may be configured to provide EBP 170B and/or EMP 170M with planar portions and/or non-planar portions. The present disclosure contemplates various configurations of the extras metal plates.

The present disclosure contemplates various configurations of capacitor structures and various configurations of the extra metal plates incorporated therein, for example, depending on a given circuit design and/or specific circuit application. In some embodiments, referring to FIGS. 2, 18A, and 18B, an IC structure 100B is similar to IC structure 100A of FIG. 1, except capacitor structure 130 includes three insulator layers, instead of two insulator layers – insulator layer 140, insulator layer 142, and an insulator layer 242. Insulator layer 242 is similar to insulator layer 140 and/or insulator layer 142. For example, insulator layer 242 includes high-k dielectric material. Insulator layer 242 is disposed between electrode layer 134 and electrode layer 136, such that top electrodes (e.g., electrode layers 134) of trench MIM stacks 152 are separated from bottom electrodes (e.g., electrode layers 136) of pillar MIM stacks 154. Further, insulator layer 142 is disposed over insulator layer 242, and both insulator layer 142 and insulator layer 242 may be disposed between conductor layer 134 and conductor layer 138.

In some embodiments, referring to FIG. 3, an IC structure 100C is similar to IC structure 100A of FIG. 1, except ETP 170T of capacitor structure 130 fills gap 175 between adjacent pillar MIM stacks 154 (e.g., between conductor layers 138 thereof). In such embodiments, passivation layer 122-4 is not disposed between adjacent pillar MIM stacks 154 of capacitor stack 150B. In some embodiments, referring to FIG. 4, an IC structure 100D is similar to IC structure 100B of FIG. 2, except ETP 170T of capacitor structure 130 fills gap 175 between adjacent pillar MIM stacks 154 (e.g., between conductor layers 138 thereof). Filling gaps between adjacent pillar MIM stacks 154, such as gap 175, with top ETP 170T may further reduce series resistance of capacitor structure 130. For example, increasing thickness of top ETP 170T, such that it fills gaps 175, may reduce sheet resistance associated with top ETP 170T and/or the top electrodes of pillar MIM stacks 154 of capacitor stack 150B, thereby reducing overall resistance of capacitor structure. The present disclosure contemplates embodiments where EMP 170M is configured to fill gaps between trench MIM stacks 152 of capacitor stack 150B and/or pillar MIM stacks 154 of capacitor stack 150A, EBP 170B is configured to fill gaps between trench MIM stacks 152 of capacitor stack 150A, or combinations thereof.

In some embodiments, referring to FIGS. 5 and 6, an IC structure 100E is similar to IC structure 100A of FIG. 1 and an IC structure 100F is similar to IC structure 100B of FIG. 2, respectively, except EBPs 170B are omitted from capacitor structures 130 thereof. In the embodiments of IC structure 100E and IC structure 100F, two electrical connections may be provided to top electrodes of pillar MIM stacks 154 of capacitor stack 150B (e.g., directly and via ETP 170T), two electrical connections may be provided to bottom electrodes of trench MIM stacks 152 of capacitor stack 150B (e.g., directly and via EMP 170M), two electrical connections may be provided to top electrodes of pillar MIM stacks 154 of capacitor stack 150A (e.g., directly and via EMP 170M), and one electrical connection may be provided to bottom electrodes of trench MIM stacks 152 of capacitor stack 150A (e.g., directly).

In some embodiments, referring to FIGS. 7 and 8, an IC structure 100G is similar to IC structure 100A of FIG. 1 and an IC structure 100H is similar to IC structure 100B of FIG. 2, respectively, except ETPs 170T are omitted from capacitor structures 130 thereof. In the embodiments of IC structure 100G and IC structure 100H, one electrical connection may be provided to top electrodes of pillar MIM stacks 154 of capacitor stack 150B (e.g., directly), two electrical connections may be provided to bottom electrodes of trench MIM stacks 152 of capacitor stack 150B (e.g., directly and via EMP 170M), two electrical connections may be provided to top electrodes of pillar MIM stacks 154 of capacitor stack 150A (e.g., directly and via EMP 170M), and two electrical connections may be provided to bottom electrodes of trench MIM stacks 152 of capacitor stack 150A (e.g., directly and via EBP 170B).

In some embodiments, referring to FIGS. 9 and 10, an IC structure 100I is similar to IC structure 100A of FIG. 1 and an IC structure 100J is similar to IC structure 100B of FIG. 2, respectively, except EMPs 170M are omitted from capacitor structures 130 thereof. In the embodiments of IC structure 100I and IC structure 100J, two electrical connections may be provided to top electrodes of pillar MIM stacks 154 of capacitor stack 150B (e.g., directly and via ETP 170T), one electrical connection may be provided to bottom electrodes of trench MIM stacks 152 of capacitor stack 150B (e.g., directly), one electrical connection may be provided to top electrodes of pillar MIM stacks 154 of capacitor stack 150A (e.g., directly), and two electrical connections may be provided to bottom electrodes of trench MIM stacks 152 of capacitor stack 150A (e.g., directly and via EBP 170B).

In some embodiments, referring to FIGS. 11 and 12, an IC structure 100K is similar to IC structure 100A of FIG. 1 and an IC structure 100L is similar to IC structure 100B of FIG. 2, respectively, except ETPs 170T and EBPs 170B are omitted from capacitor structures 130 thereof. In the embodiments of IC structure 100K and IC structure 100L, one electrical connection may be provided to top electrodes of pillar MIM stacks 154 of capacitor stack 150B (e.g., directly), two electrical connections may be provided to bottom electrodes of trench MIM stacks 152 of capacitor stack 150B (e.g., directly and via EMP 170M), two electrical connections may be provided to top electrodes of pillar MIM stacks 154 of capacitor stack 150A (e.g., directly and via EMP 170M), and one electrical connection may be provided to bottom electrodes of trench MIM stacks 152 of capacitor stack 150A (e.g., directly).

In some embodiments, referring to FIGS. 13 and 14, an IC structure 100M is similar to IC structure 100A of FIG. 1 and an IC structure 100N is similar to IC structure 100B of FIG. 2, respectively, except ETPs 170T and EMPs 170M are omitted from capacitor structures 130 thereof. In the embodiments of IC structure 100M and IC structure 100N, one electrical connection may be provided to top electrodes of pillar MIM stacks 154 of capacitor stack 150B (e.g., directly), one electrical connection may be provided to bottom electrodes of trench MIM stacks 152 of capacitor stack 150B (e.g., directly), one electrical connection may be provided to top electrodes of pillar MIM stacks 154 of capacitor stack 150A (e.g., directly), and two electrical connections may be provided to bottom electrodes of trench MIM stacks 152 of capacitor stack 150A (e.g., directly and via EBP 170B).

In some embodiments, referring to FIGS. 15 and 16, an IC structure 100O is similar to IC structure 100A of FIG. 1 and an IC structure 100P is similar to IC structure 100B of FIG. 2, respectively, except EMPs 170M and EBPs 170B are omitted from capacitor structures 130 thereof. In the embodiments of IC structure 100O and IC structure 100P, two electrical connections may be provided to top electrodes of pillar MIM stacks 154 of capacitor stack 150B (e.g., directly and via ETP 170T), one electrical connection may be provided to bottom electrodes of trench MIM stacks 152 of capacitor stack 150B (e.g., directly), one electrical connection may be provided to top electrodes of pillar MIM stacks 154 of capacitor stack 150A (e.g., directly), and one electrical connection may be provided to bottom electrodes of trench MIM stacks 152 of capacitor stack 150A (e.g., directly).

The present disclosure contemplates various layouts and/or configurations of capacitor structure 130 of IC structures 100A–100O, such as depicted in FIG. 21. As described herein, capacitor structure 130 includes MIM units 156, which may be formed from electrode layers 132, electrode layers 134, electrode layers 136, electrode layers 138, insulator layers 140, and insulator layers 142. In some embodiments, such as depicted, MIM units 156 may be arranged with uniform spacing therebetween and/or uniform widths, and MIM units 156 may have different lengths. The electrode layers of capacitor structure 130 may be patterned to have openings (or islands) therein for receiving a respective via (e.g., metal via 160A or metal via 160B) therein. The openings may be configured to ensure proper placement of the respective via, for example, ensuring the respective via contacts some electrode layers without contacting other electrode layers. For ease and simplicity of description, electrode layer 132, electrode layer 134, and electrode layer 138 of capacitor stack 150A (i.e., the electrodes disposed in passivation layer 122-1 and passivation layer 122-2) are illustrated in FIG. 21, and electrode layer 136, which is formed into metal pillars on electrode layer 134, is omitted from FIG. 21. In some embodiments, electrode layer 132 of capacitor stack 150A has an opening 260 therein, electrode layer 134 of capacitor stack 150A has an opening 262 therein, and electrode layer 138 of capacitor stack 150A has an opening 264 therein. Though electrode layer 132, electrode layer 134, and electrode layer 138 of capacitor stack 150B (i.e., the electrodes disposed in passivation layer 122-3 and passivation layer 122-4) are omitted from FIG. 21, electrode layer 132, electrode layer 134, and electrode layer 138 of capacitor stack 150B may be configured with similar dimensions, shapes, locations, openings therein, or combinations thereof as electrode layer 132, electrode layer 134, and electrode layer 138, respectively, of capacitor stack 150A.

Various dimensions may be designed for enhancing packing density, capacitance, pattern density, and the like associated with capacitor structure 130. For example, electrode layer 132 has a width Wc, RDL lines contacting the metal vias (e.g., RDL line 162A and RDL line 162B disposed on metal via 160A and metal via 160B, respectively) have a width Wr, and top metal lines of MLI structure 110 (e.g., metal line 114A and metal line 114B) have a width Wm. Spacing S1 may define a spacing between MIM units 156 and a closest edge/boundary of the electrode layers (e.g., an edge of electrode layer 138), spacing S2 may define a spacing between MIM units 156 and openings in the electrode layers (e.g., opening 260 in electrode layer 132), and spacing S3 may define a margin between boundaries/edges of openings in the electrode layers (e.g., between opening 260 in electrode layer 132 and opening 264 in electrode layer 138). M1 may define a margin between a metal via (e.g., metal via 160B) and a top metal line (e.g., metal line 114A), M2 may define a margin between a metal via (e.g., metal via 160B) and an RDL line (e.g., RDL line 162A), and M3 and M4 define margins between respective edges of electrode layer 134 and electrode layer 138. A dimension Do may correspond with a spacing between MIM units 156 that corresponds with a via area (i.e., an area where a metal via, such as metal via 160A, may be formed). In some embodiments, MIM unit 156 may be configured with one or more of the following: width Wc of about 1 µm to about 300 µm; width Wr of about 1.2 µm to about 35 µm; width Wm of about 1.2 µm to about 20 µm; spacing S1 of at least 0.1 µm; spacing S2 of at least 0.1 µm; spacing S3 of about 0.05 µm to about 0.2 µm; M1 of at least 0.2 µm; M2 of at least 0.2 µm; M3 of about 0.05 µm to about 0.2 µm; M4 of about 0.05 µm to about 0.2 µm; and Do of about 2.5 µm to about 5 µm. In some embodiments, a pitch (e.g., pitch P) of MIM units 156 may be about 0.2 µm to about 0.8 µm. In some embodiments, the metal vias (e.g., metal via 160A and/or metal via 160B) have widths and/or lengths that are about 0.8 µm to about 2.7 µm. In such embodiments, the metal vias may be configured to have dimensions of about 0.8 µm x 0.8 µm to about 2.7 µm x 2.7 µm.

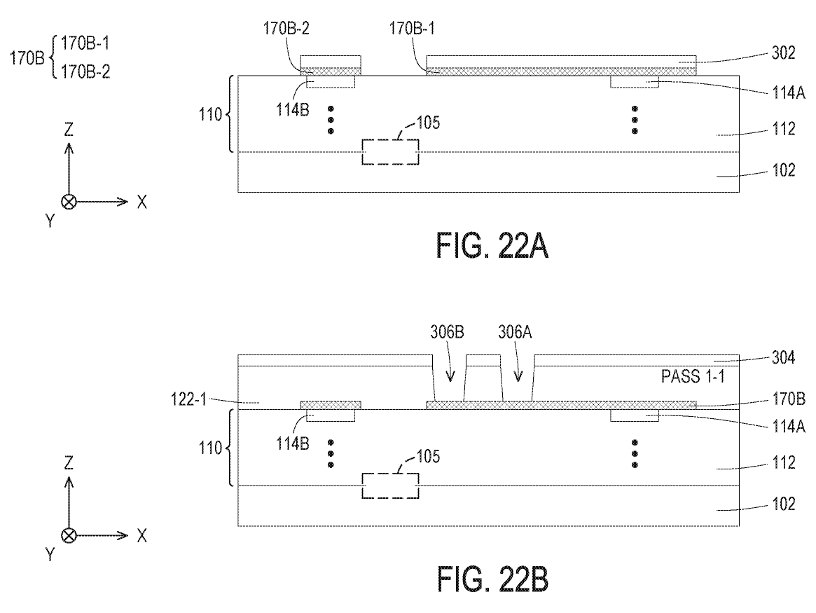

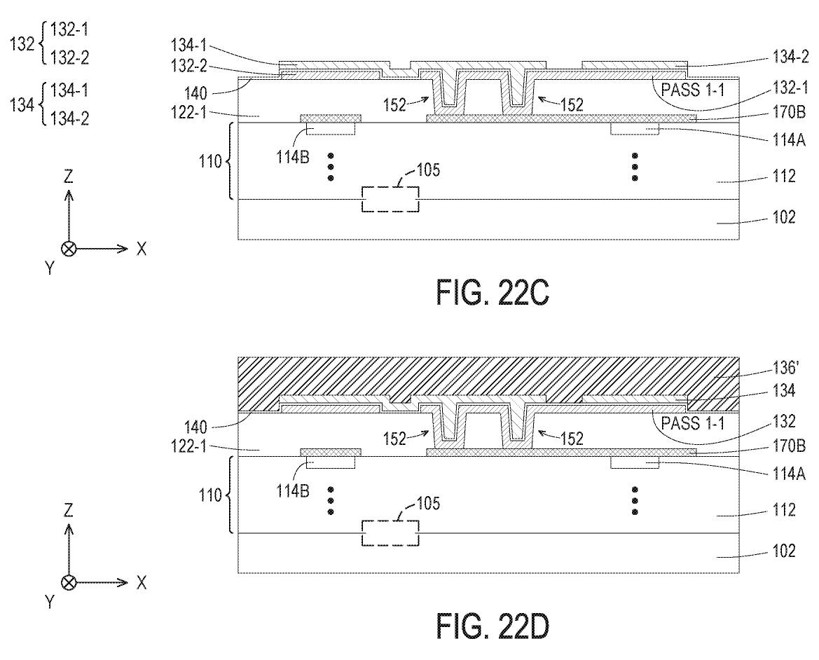

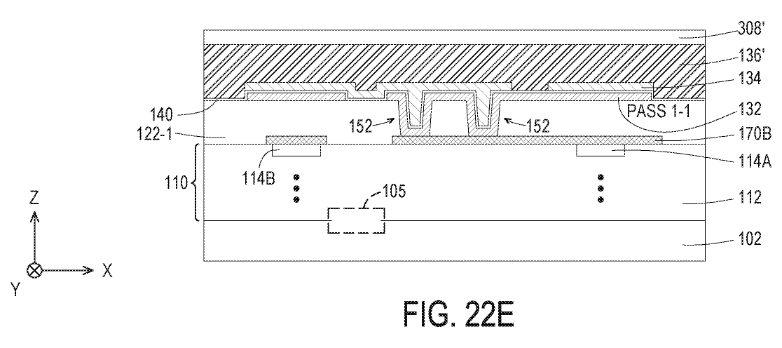

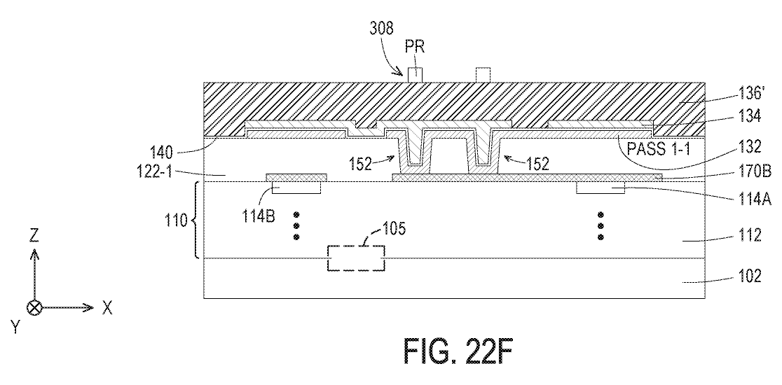

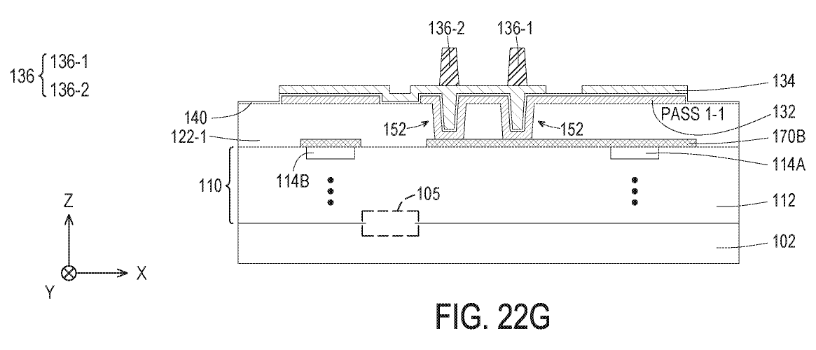

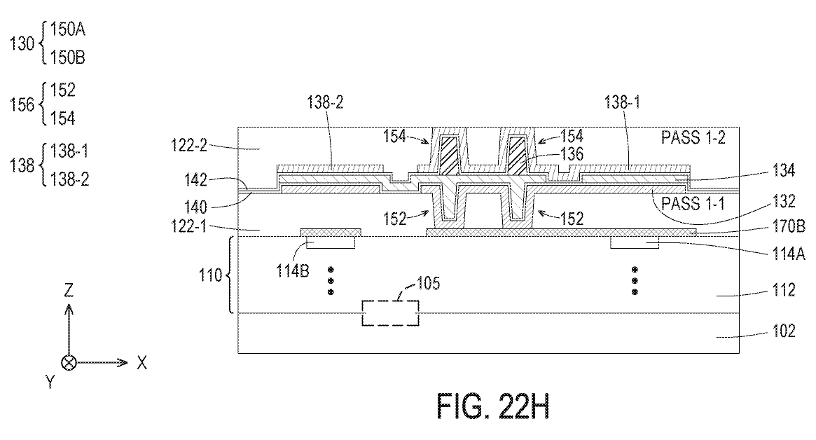

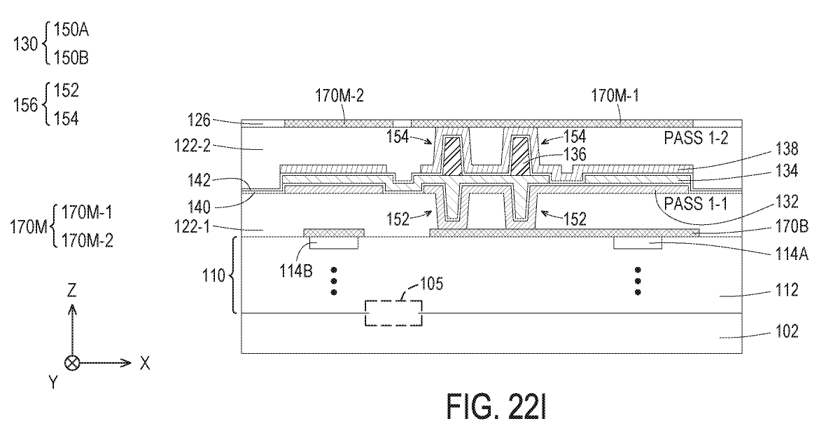

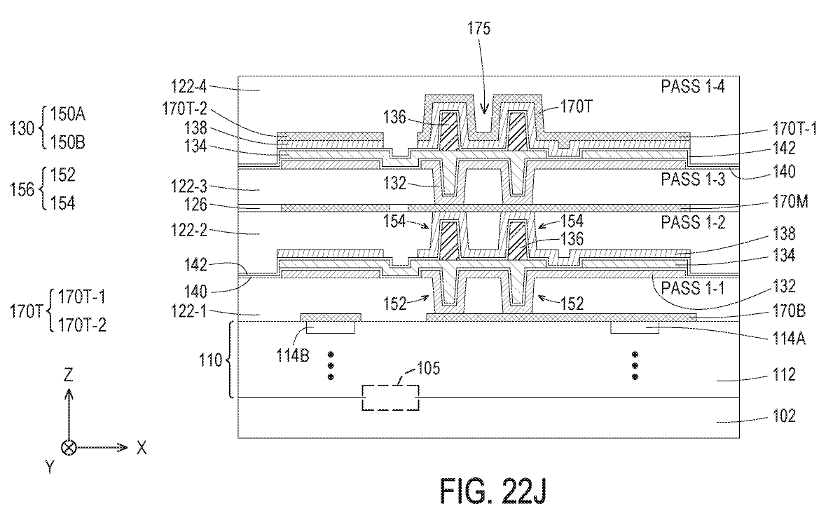

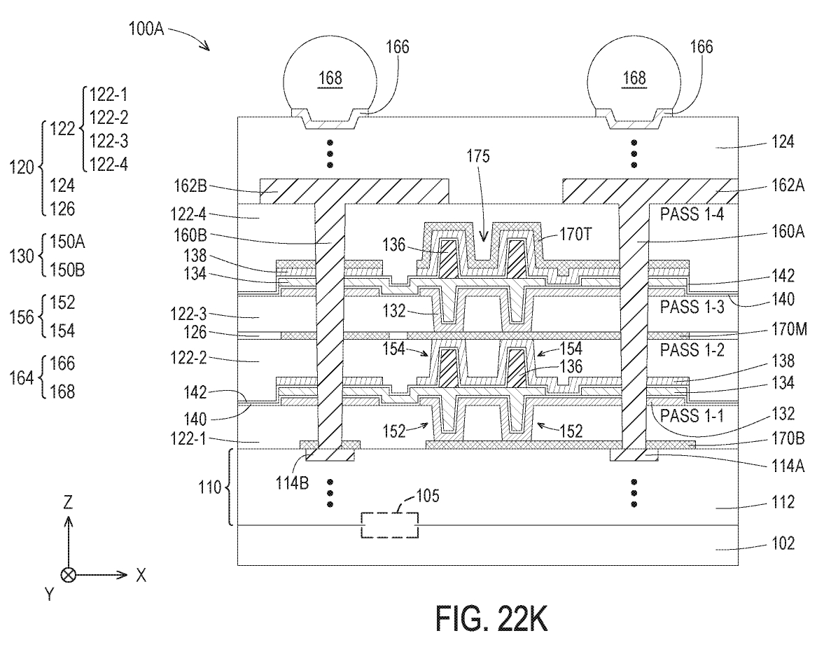

FIGS. 22A–22K are diagrammatic cross-sectional views of an IC structure, such as IC structure 100A of FIG. 1, in portion or entirety, at various stages of fabrication of a stacked capacitor structure thereof, such as capacitor structure 130, according to various aspects of the present disclosure. FIGS. 22A–22K have been simplified for the sake of clarity to better understand the inventive concepts of the present disclosure. Additional steps can be provided before, during, and after the various stages of fabrication, and some of the steps described can be moved, replaced, or eliminated for additional embodiments of the various stages of fabrication. Additional features can be added in the IC structure, and some of the features described below can be replaced, modified, or eliminated in other embodiments of the IC structure.

Referring FIG. 22A, an extra metal plate, such as EBP 170B, is formed over an MLI structure, such as MLI structure 110. EBP 170B may be formed by depositing a metal layer (and/or other electrically conductive material layer) over MLI structure 110, forming a patterning layer 302 over the metal layer, and etching the metal layer using the patterning layer 302 as an etch mask. Patterning layer 302 may include openings therein that expose portions of the metal layer, and the exposed portions of the metal layer may be removed by the etching (e.g. a dry etching and/or a wet etching). Remaining portions of the metal layer (which are covered by patterning layer 302) form EBP 170B. In some embodiments, EBP 170B is a patterned metal layer that includes multiple portions/segments. For example, EBP 170B may include an EBP segment 170B-1 disposed on metal line 114A and an EBP segment 170B-2 disposed on metal line 114B, and EBP segment 170B-1 may be separate from (e.g., not connected to) EBP segment 170B-2. Patterning layer 302 may be formed by a lithography process, and patterning layer 302 may include a resist layer, a hard mask layer, or combinations thereof. The depositing may include chemical vapor deposition (CVD), physical vapor deposition (PVD), atomic layer deposition (ALD), other suitable deposition process, or combinations thereof. In some embodiments, a thickness of the metal layer (and thus EBP 170B) is about 200 Å to about 700 Å. In some embodiments, the metal layer (and thus EBP 170B) is a titanium nitride layer.

Referring to FIG. 22B, a passivation layer, such as passivation sublayer 122-1, may be formed over EBP 170B and MLI structure 110 (e.g., insulation layer 112 thereof). Passivation sublayer 122-1 may be formed by CVD, PVD, ALD, other suitable process, or combinations thereof. In some embodiments, passivation sublayer 122-1 is formed of a dielectric material that includes silicon and carbon and/or nitrogen. For example, passivation sublayer 122-1 may be a silicon nitride layer. In some embodiments, a thickness of passivation sublayer 122-1 is about 1,000 Å to about 10,000 Å. Patterning layer 302 may be removed (e.g., by resist stripping, resist ashing, etching, other suitable process, or combinations thereof) from over EBP 170B before forming passivation sublayer 122-1.

Fabrication may further include forming a patterning layer 304 over passivation sublayer 122-1 and etching passivation sublayer 122-1 using the patterning layer 304 as an etch mask. Patterning layer 304 may include openings therein that expose portions of passivation sublayer 122-1, and the exposed portions of passivation sublayer 122-1 may be removed by the etching (e.g. a dry etching and/or a wet etching) to form trenches therein, such as a trench 306A and a trench 306B, that expose EBP 170B (e.g., EBP segment 170B-b thereof). The etching may extend the openings in patterning layer 304 downwards (e.g., vertically in a direction towards device substrate 102). Trench 306A and trench 306B may have tapered/slanted sidewalls, such that trench 306A and trench 306B may have trapezoidal cross-sectional profiles. The present disclosure contemplates trench 306A and trench 306B having other sidewall configurations and different shaped cross-sectional profiles. Remaining portions of passivation sublayer 122-1 (which are covered by patterning layer 304 during the etching) may form a portion of passivation layer 122. Patterning layer 304 may be formed by a lithography process, and patterning layer 304 may include a resist layer, a hard mask layer, or combinations thereof.

Referring to FIG. 22C, patterning layer 304 may be removed (e.g., by resist stripping, resist ashing, etching, other suitable process, or combinations thereof) from over passivation sublayer 122-1. Thereafter, an electrode layer, such as electrode layer 132, is formed, for example, by depositing a metal layer (and/or other electrically conductive material layer) over passivation sublayer 122-1 that partially fills trench 306A and trench 306B (e.g., along sidewalls thereof formed by passivation sublayer 122-1 and bottoms thereof formed by EBP 170B), forming a patterning layer over the metal layer, and etching the metal layer using the patterning layer as an etch mask. The depositing may include CVD, PVD, ALD, other suitable deposition process, or combinations thereof. In some embodiments, a thickness of the metal layer (and thus electrode layer 132) is about 200 Å to about 700 Å. In some embodiments, the metal layer (and thus electrode layer 132) is a titanium nitride layer formed by ALD.

The patterning layer may be formed by a lithography process, and the patterning layer may include a resist layer, a hard mask layer, or combinations thereof. The patterning layer includes openings therein that expose portions of the metal layer, and the exposed portions of the metal layer may be removed by the etching (e.g. a dry etching and/or a wet etching). Remaining portions of the metal layer (which are covered by the patterning layer) form electrode layer 132. In some embodiments, the etching removes a segment of the metal layer disposed on passivation sublayer 122-1 that is between metal line 114B and trench 306B and segments of the metal layer disposed on passivation sublayer 122-1 at edges of IC structure 100A. As a result, electrode layer 132 is a patterned metal layer that includes multiple portions/segments. For example, electrode layer 132 may include an electrode segment 132-1 disposed on EBP segment 170B-1 and an electrode segment 132-2 disposed on passivation sublayer 122-1. Electrode segment 132-1 is thus separated from and/or electrically isolated from electrode segment 132-2 by an opening formed in the metal layer by the etching that exposes a portion of passivation sublayer 122-1 between metal line 114B and trench 306B. It is noted that electrode segment 132-2 is separated and/or electrically isolated from EBP segment 170B-2 by passivation sublayer 122-1.

After forming electrode layer 132, an insulator layer, such as insulator layer 140, may be formed over electrode layer 132 and passivation sublayer 122-1. The insulator layer partially fills trench 306A and trench 306B, and the insulator layer partially fills an opening in electrode layer 132 between electrode segment 132-1 and electrode segment 132-2. Insulator layer helps electrically isolate electrode segment 132-1 from electrode segment 132-2. In other words, an electrical signal cannot propagate from electrode segment 132-1 to electrode segment 132-2 (or vice versa) through the insulator layer. The insulator layer may be formed by CVD, PVD, ALD, other suitable process, or combinations thereof. A thickness of the insulator layer is less than a thickness of the electrode layer. In some embodiments, a thickness of the insulator layer (and thus insulator layer 140) is about 40 Å to about 80 Å. In some embodiments, the insulator layer (and thus insulator layer 140) is a high-k dielectric layer, such as described herein.

After forming insulator layer 140, another electrode layer, such as electrode layer 134, is formed, for example, by depositing a metal layer (and/or other electrically conductive material layer) over insulator layer 140 that fills remainders of trench 306A and trench 306B, forming a patterning layer over the metal layer, and etching the metal layer using the patterning layer as an etch mask. In some embodiments, such as depicted, the metal layer may also fill a remainder of the opening in electrode layer 132 between electrode segment 132-1 and electrode segment 132-2. The depositing may include CVD, PVD, ALD, other suitable deposition process, or combinations thereof. In some embodiments, a thickness of the metal layer (and thus electrode layer 134) is about 200 Å to about 700 Å. In some embodiments, the metal layer (and thus electrode layer 134) is a titanium nitride layer formed by ALD.

The patterning layer may be formed by a lithography process, and the patterning layer may include a resist layer, a hard mask layer, or combinations thereof. The patterning layer includes openings therein that expose portions of the metal layer, and the exposed portions of the metal layer may be removed by the etching (e.g. a dry etching and/or a wet etching). Remaining portions of the metal layer (e.g., those portions covered by the patterning layer) form electrode layer 134. In some embodiments, the etching removes a segment of the metal layer disposed on a portion of the insulator layer 140 that is between metal line 114A and trench 306A and segments of the metal layer disposed on portions of insulator layer 140 at edges of IC structure 100A. As a result, electrode layer 134 is a patterned metal layer that includes multiple portions/segments, such as an electrode segment 134-1 and an electrode segment 134-2. Electrode segment 134-1 is disposed over both electrode segment 132-1 and electrode segment 132-2. Electrode segment 134-1 fills trench 306A and trench 306B, and electrode segment 134-1 may fill a remainder of the opening in electrode layer 132 between electrode segment 132-1 and electrode segment 132-2. Electrode segment 134-2 is disposed over a portion of electrode segment 132-1 that extends over metal line 114A. Electrode segment 134-1 is separated and/or electrically isolated from electrode segment 134-2 by an opening formed by the etching that exposes a portion of insulator layer 140 between metal line 114A and trench 306A.

Referring to FIGS. 22D–22G, after forming electrode layer 134, another electrode layer, such as electrode layer 136, is formed, for example, by depositing a metal layer 136’ (and/or other electrically conductive material layer) over electrode layer 134 and insulator layer 140 (FIG. 22D), forming a patterning material 308’ (e.g., a resist material) over metal layer 136’ (FIG. 22E), performing a lithography process and/or an etching process on patterning material 308’ to form a patterning layer 308 over metal layer 306’ (FIG. 22F), and etching metal layer 136’ using patterning layer 308 as an etch mask (FIG. 22G). In some embodiments, such as depicted, metal layer 136’ may fill the opening in electrode layer 134 between electrode segment 134-1 and electrode segment 134-2. The depositing may include CVD, PVD, ALD, other suitable deposition process, or combinations thereof. In some embodiments, a thickness of metal layer 136’ (and thus electrode layer 136) is about 200 Å to about 700 Å. In some embodiments, metal layer 136’ (and thus electrode layer 136) is a titanium nitride layer formed by ALD. In some embodiments, metal layer 136’ is a titanium nitride layer formed by PVD.

Patterning material 308’ may be formed by any suitable process (e.g., spin-on coating of a resist material and/or depositing of a hard mask material), and patterning layer 308 may include a resist layer, a hard mask layer, or combinations thereof. Patterning layer 308 includes openings therein that expose portions of metal layer 136’, and the exposed portions of metal layer 136’ may be removed by the etching (e.g. a dry etching and/or a wet etching). Remaining portions of metal layer 136’ (which are covered by patterning layer 308) form electrode layer 136. In some embodiments, the etching removes a segment of metal layer 136’ disposed on a portion of electrode segment 134-1 that is between trench 306A and trench 306B, a segment of metal layer 136’ disposed on electrode segment 134-1 that extends over metal line 114B, a segment of metal layer 136’ disposed on electrode segment 134-2, and segments of metal layer 136’ disposed on insulator layer 140. As a result, electrode layer 136 is a patterned metal layer that includes multiple portions/segments. For example, electrode layer 136 may include an electrode segment 136-1 and an electrode segment 136-2. Electrode segment 136-1 and electrode segment 136-2 are disposed over electrode segment 134-1, and electrode segment 136-1 and electrode segment 136-2 overlap and are aligned with (e.g., center aligned) trench 306B and trench 306A, respectively. Electrode segment 136-1 and electrode segment 136-2 extend upwards (e.g., vertically in a direction away device substrate 102). Electrode segment 136-1 and electrode segment 136-2 may have tapered/slanted sidewalls, such that electrode segment 136-1 and electrode segment 136-2 may have trapezoidal cross-sectional profiles. The present disclosure contemplates electrode segment 136-1 and electrode segment 136-2 having other sidewall configurations and different shaped cross-sectional profiles. In some embodiments, as depicted, electrode segment 136-1 and electrode segment 136-2 are formed directly on electrode segment 134-1. In some embodiments, the etching of metal layer 136’ is controlled by etch time. The etching may stop upon reaching insulator layer 140 and/or electrode layer 134.

Referring to FIG. 22H, after forming electrode layer 136, an insulator layer, such as insulator layer 142, may be formed over electrode layer 136, electrode layer 134, and insulation layer 140. The insulator layer may partially fill an opening in electrode layer 134 between electrode segment 134-1 and electrode segment 134-2 and an opening in electrode layer 136 between electrode segment 136-1 and electrode segment 136-2. The insulator layer may thus help electrically isolate electrode segment 134-1 from electrode segment 134-2 and/or electrode segment 136-1 and electrode segment 136-2. The insulator layer may be formed by CVD, PVD, ALD, other suitable process, or combinations thereof. A thickness of the insulator layer is less than a thickness of the electrode layer. In some embodiments, a thickness of the insulator layer (and thus insulator layer 142) is about 40 Å to about 80 Å. In some embodiments, the insulator layer (and thus insulator layer 142) is a high-k dielectric layer, such as described herein.

After forming insulator layer 142, another electrode layer, such as electrode layer 138, is formed, for example, by depositing a metal layer (and/or other electrically conductive material layer) over insulator layer 142, forming a patterning layer over the metal layer, and etching the metal layer using the patterning layer as an etch mask. In some embodiments, the metal layer fills a remainder the opening in electrode layer 134 between electrode segment 134-1 and electrode segment 134-2. In some embodiments, such as depicted, the metal layer partially fills the opening in electrode layer 136 between electrode segment 136-1 and electrode segment 136-2. The depositing may include CVD, PVD, ALD, other suitable deposition process, or combinations thereof. In some embodiments, a thickness of the metal layer (and thus electrode layer 138) is about 200 Å to about 700 Å. In some embodiments, the metal layer (and thus electrode layer 138) is a titanium nitride layer formed by ALD.

The patterning layer may be formed by a lithography process, and the patterning layer may include a resist layer, a hard mask layer, or combinations thereof. The patterning layer includes openings therein that expose portions of the metal layer, and the exposed portions of the metal layer may be removed by the etching (e.g. a dry etching and/or a wet etching). Remaining portions of the metal layer (e.g., those portions covered by the patterning layer) form electrode layer 138. In some embodiments, the etching removes a segment of the metal layer disposed on a portion of insulator layer 142 that is between metal line 114B and trench 306B and segments of the metal layer disposed on portions of insulator layer 142 at edges of IC structure 100A. As a result, electrode layer 138 is a patterned metal layer that includes multiple portions/segments, such as an electrode segment 138-1 and an electrode segment 138-2. Electrode segment 138-1 is disposed over both electrode segment 134-1 and electrode segment 134-2. Electrode segment 138-1 may fill a remainder of the opening in electrode layer 134 between electrode segment 134-1 and electrode segment 134-2. Electrode segment 138-2 is disposed over a portion of electrode segment 134-1 that extends over metal line 114B. Electrode segment 138-1 is separated and/or electrically isolated from electrode segment 138-2 by an opening formed by the etching that exposes a portion of insulator layer 142 between metal line 114B and trench 306B.

After forming electrode layer 138, the patterning layer may be removed (e.g., by resist stripping, resist ashing, etching, other suitable process, or combinations thereof). As a result of the above processing, capacitor structure 130 includes capacitor stack 150A, which includes trench MIM stacks 152 and pillar MIM stacks 154, which may be configured as MIM units 156 arranged according to various configurations, such as described herein. A passivation layer, such as passivation sublayer 122-2, may then be formed over electrode layer 138 and insulator layer 142. Passivation sublayer 122-2 may be formed by CVD, PVD, ALD, other suitable process, or combinations thereof. In some embodiments, a planarization process, such as a chemical mechanical polishing (CMP) process, may be performed after depositing a passivation material. The planarization process may remove any of the passivation material above tops of electrode layer 138 and/or stop upon reaching electrode layer 138, such that passivation sublayer 122-2 and electrode layer 138 form an upper, planarized surface over which subsequent layers of IC structure 100A may be formed. In some embodiments, passivation sublayer 122-2 is formed of a dielectric material that includes silicon and carbon and/or nitrogen. For example, passivation sublayer 122-2 may be a silicon nitride layer. In some embodiments, a thickness of passivation sublayer 122-2 is about 1,000 Å to about 10,000 Å.

Referring to FIG. 22I, an extra metal plate, such as EMP 170M, is formed over passivation sublayer 122-2 and electrode layer 138. EMP 170M may be formed as described above with reference to EBP 170B. For example, EMP 170M may be formed by depositing a metal layer (and/or other electrically conductive material layer) over passivation sublayer 122-2 and electrode layer 138, forming a patterning layer over the metal layer, and etching the metal layer using the patterning layer as an etch mask. The patterning layer may include openings therein that expose portions of the metal layer, and the exposed portions of the metal layer may be removed by the etching (e.g. a dry etching and/or a wet etching). Remaining portions of the metal layer (which are covered by the patterning layer) form EMP 170M. In some embodiments, EMP 170M is a patterned metal layer that includes multiple portions/segments. For example, EMP 170M may include an EMP segment 170M-1 and an EMP segment 170M-2. EMP segment 170M-1 is disposed on electrode segment 138-1 and extends over metal line 114A, and EMP segment 170M-2 is disposed on a portion of passivation sublayer 122-2 over metal line 114B. EMP segment 170M-1 may be separate from (e.g., not connected to) EMP segment 170M-2. The patterning layer 302 may be formed by a lithography process, and the patterning layer may include a resist layer, a hard mask layer, or combinations thereof. The depositing may include CVD, PVD, ALD, other suitable deposition process, or combinations thereof. In some embodiments, a thickness of the metal layer (and thus EMP 170M) is about 200 Å to about 700 Å. In some embodiments, the metal layer (and thus EMP 170M) is a titanium nitride layer.

Referring to FIG. 22J, capacitor stack 150B, a portion of which is embedded in passivation sublayer 122-3, is formed over capacitor stack 150A. In some embodiments, passivation sublayer 122-3 is formed directly on EMP 170M, and EMP 170M is embedded in passivation sublayer 122-3. In some embodiments, before forming passivation sublayer 122-3, passivation layer 126 is formed over passivation sublayer 122-2 and electrode layer 138 of capacitor stack 150A. In some embodiments, passivation layer 126 is formed by depositing a passivation material and performing a planarization process to remove any of the passivation material from over EMP 170M, such that passivation layer 126 and EMP 170M form an upper, planarized surface. In such embodiments, EMP 170M may function as a planarization stop layer. In some embodiments, forming EMP 170M includes forming passivation layer 126 over passivation sublayer 122-2 and electrode layer 138 of capacitor stack 150A, patterning passivation layer 126 to have openings therein (e.g., one of which exposes electrode segment 138-1 of capacitor stack 150A), depositing electrically conductive material in the openings of passivation layer 126, and performing a planarization process (e.g., CMP), such that passivation layer 126 and EMP 170M form an upper, planarized surface. In some embodiments, passivation sublayer 122-3 and/or passivation layer 126 is formed of a dielectric material that includes silicon and carbon and/or nitrogen. For example, passivation sublayer 122-3 and/or passivation layer 126 may be a silicon nitride layer. In some embodiments, a thickness of passivation sublayer 122-3 is about 1,000 Å to about 10,000 Å. A thickness of passivation layer 126 is less than a thickness of passivation sublayers of passivation layer 122. In some embodiments, a thickness of passivation sublayer 126 is about 200 Å to about 700 Å.

Capacitor stack 150B may be formed as described above with reference to capacitor stack 150A and FIGS. 22B–22H. Thereafter, an extra metal plate, such as ETP 170T, is formed over electrode layer 138 of capacitor stack 150B. ETP 170T may be formed as described above with reference to EBP 170B. For example, ETP 170T may be formed by depositing a metal layer (and/or other electrically conductive material layer) over electrode layer 138 and insulator layer 142, forming a patterning layer over the metal layer, and etching the metal layer using the patterning layer as an etch mask. In some embodiments, such as depicted, the metal layer partially fills the opening in electrode layer 136 between electrode segment 136-1 and electrode segment 136-2. In some embodiments, the metal layer partially fills remainders of the opening in electrode layer 136 between electrode segment 136-1 and electrode segment 136-2.

The patterning layer may include openings therein that expose portions of the metal layer, and the exposed portions of the metal layer may be removed by the etching (e.g. a dry etching and/or a wet etching). Remaining portions of the metal layer (which are covered by the patterning layer) form ETP 170T. In some embodiments, ETP 170T is a patterned metal layer that includes multiple portions/segments. For example, ETP 170T may include an ETP segment 170T-1 and an ETP segment 170T-2. ETP segment 170T-1 is disposed on electrode segment 138-1 and extends over metal line 114A, and ETP segment 170T-2 is disposed on a portion of electrode segment 138-2. ETP segment 170T-1 may be separate from (e.g., not connected to) ETP segment 170T-2. The patterning layer may be formed by a lithography process, and the patterning layer may include a resist layer, a hard mask layer, or combinations thereof. The depositing may include CVD, PVD, ALD, other suitable deposition process, or combinations thereof. In some embodiments, a thickness of the metal layer (and thus ETP 170T) is about 200 Å to about 700 Å. In some embodiments, the metal layer (and thus ETP 170T) is a titanium nitride layer. In some embodiments, ETP 170T and electrode layer 138 of capacitor stack 150B may be formed using the same pattering process. For example, before patterning a first metal layer forming electrode layer 138, a second metal layer forming ETP 170T may be deposited over the first metal layer, a patterning layer may be formed over the second metal layer, and the patterning layer may be used as an etch mask to pattern both the second metal layer (i.e., ETP 170T) and the first metal layer (e.g., electrode 138).

As a result of the above processing, capacitor structure 130 includes capacitor stack 150A and capacitor stack 150B. A passivation layer, such as passivation sublayer 122-4, may then be formed over electrode layer 138 and insulator layer 142 of capacitor stack 150B. Passivation layer 122-4 is not removed from over and remains covering tops of capacitor stack 150B of capacitor structure 150B. Passivation sublayer 122-4 may be formed by CVD, PVD, ALD, other suitable process, or combinations thereof. In some embodiments, a planarization process may be performed on passivation sublayer 122-4. In some embodiments, passivation sublayer 122-4 is formed of a dielectric material that includes silicon and carbon and/or nitrogen. For example, passivation sublayer 122-4 may be a silicon nitride layer. In some embodiments, a thickness of passivation sublayer 122-4 is about 1,000 Å to about 10,000 Å.

Referring to FIG. 22K, processing includes forming metal vias, such as metal via 160A and metal via 160B, that extend through capacitor stack 150A, capacitor stack 150B, and any extra metal plates of capacitor structure 130 (in the depicted embodiment, EBP 170B, EMP 170M, and ETP 170T). Forming metal vias may include forming a patterning layer (such as described herein) over passivation sublayer 122-4 and etching passivation layer 122, capacitor stack 150A, capacitor stack 150B, and extra metal plates using the patterning layer as an etch mask. The patterning layer may include openings therein that expose a first portion of passivation sublayer 122-4 overlapping metal line 114A and a second portion of passivation sublayer 122-4 overlapping metal line 114B. The etching (e.g. a dry etching and/or a wet etching) may remove the first exposed portion of passivation sublayer 122-4 and exposed material layers (e.g., passivation sublayer 122-3, passivation sublayer 122-2, passivation sublayer 122-1, capacitor stack 150A, capacitor stack 150B, EBP 170B, EMP 170M, and ETP 170T) underlying the first exposed portion of passivation sublayer 122-4 to form a first via trench that exposes metal line 114A. The etching may also remove the second exposed portion of passivation sublayer 122-4 and exposed material layers underlying the second exposed portion of passivation sublayer 122-4 to form a second via trench that exposes metal line 114B. The etching may extend the openings in the patterning layer downwards (e.g., in a direction towards device substrate 102). The first via trench and the second via trench may have tapered/slanted sidewalls, such that the first via trench and the second via trench may have trapezoidal cross-sectional profiles. The present disclosure contemplates the first via trench and the second via trench having other sidewall configurations and different shaped cross-sectional profiles.

After removing the patterning layer (such as described herein), metal via 160A and metal via 160B are formed in the first via trench and the second via trench, for example, by depositing electrically conductive material(s) over passivation sublayer 122-4 that fill the first via trench and the second via trench. The depositing may include CVD, PVD, ALD, electrochemical plating deposition (ECP), other suitable deposition process, or combinations thereof. In some embodiments, the depositing includes depositing a via barrier/seed layer by PVD and depositing a metal via plug on the barrier/seed layer by ECP. In some embodiments, a planarization process is performed to remove the electrically conductive material(s) from over passivation sublayer 122-4, such that passivation sublayer 122-4, metal via 160A, and metal via 160B form an upper, planarized surface over which RDL line 162A, RDL line 162B, and passivation layer 124 may be formed. In some embodiments, a planarization process is performed to provide the electrically conductive material(s) with an upper, planarized surface, and the electrically conductive material(s) over a top of passivation sublayer 122-4 may be patterned to form RDL line 162A and RDL line 162B over metal via 160A and metal via 160B, respectively. In such embodiments, passivation layer 124 and additional RDL lines/vias formed therein may be formed over passivation layer 122, RDL line 162A, and RDL line 162B. In some embodiments, the RDL formation process 410 may include an electroplating process to form the various types of conductive materials of the RDL structures. In some embodiments, a height and/or a total thickness of a metal via/RDL line pair (e.g., RDL line 162A and metal via 160A) is about 10,000 Å to about 50,000 Å. In some embodiments, a thickness of passivation layer 124 is about 1,000 Å to about 10,000 Å. After forming passivation layer 124 and RDL structure therein, processing may include forming connectors 164.

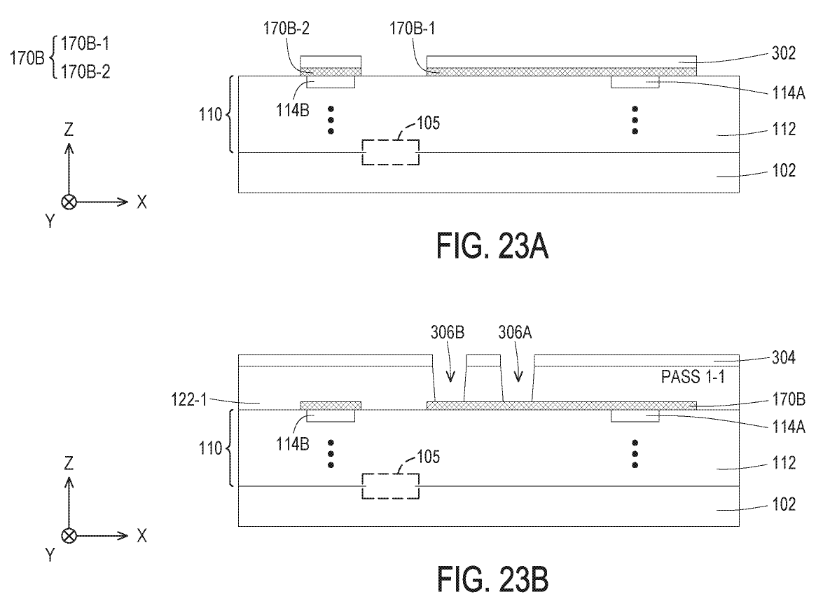

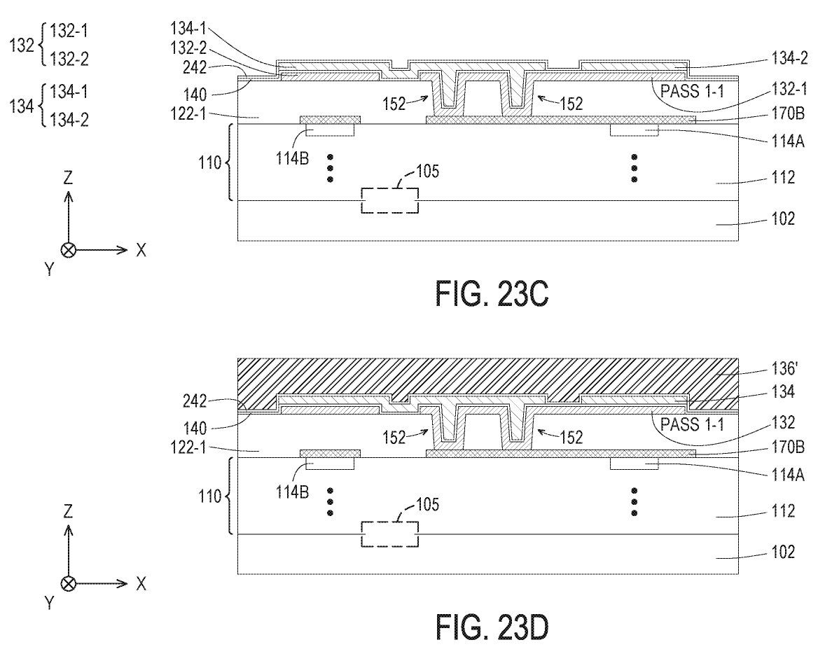

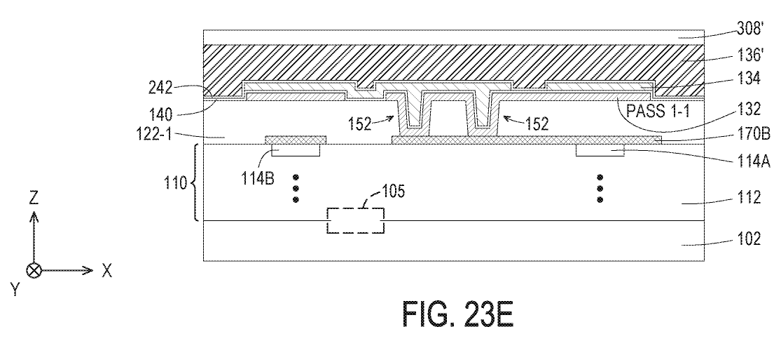

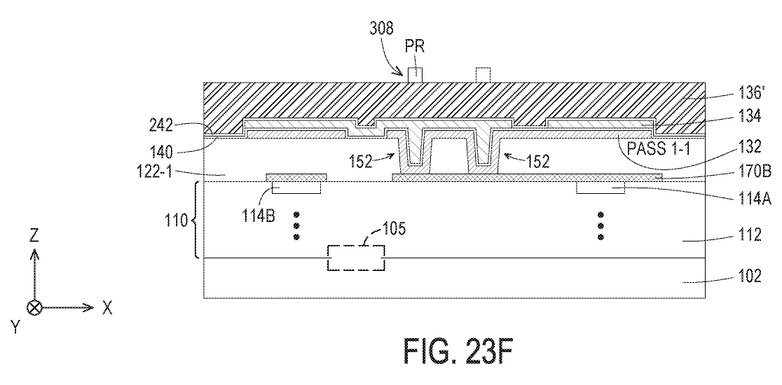

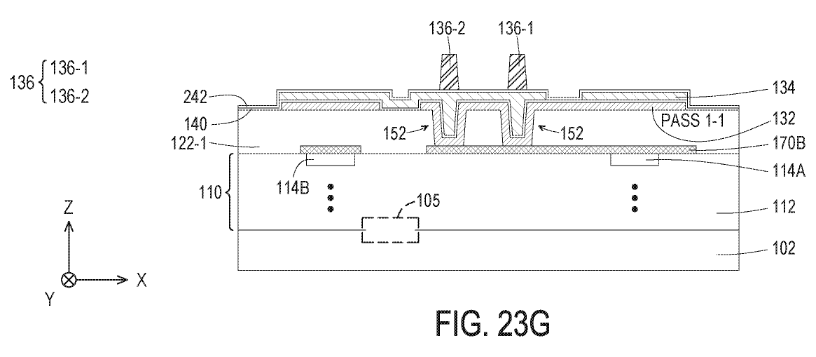

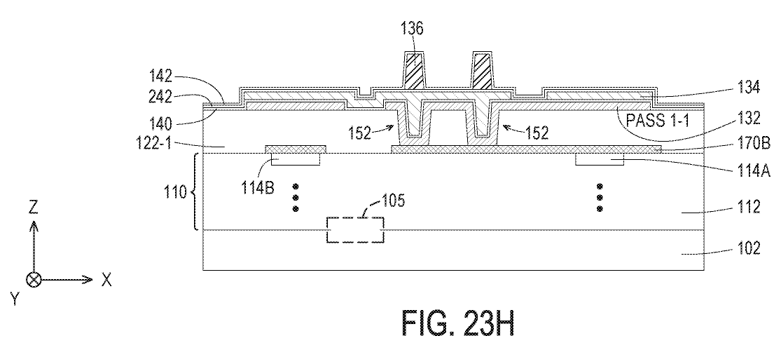

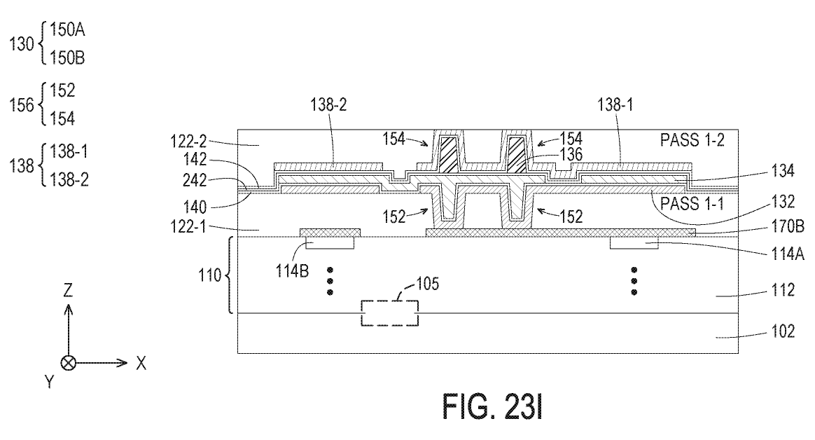

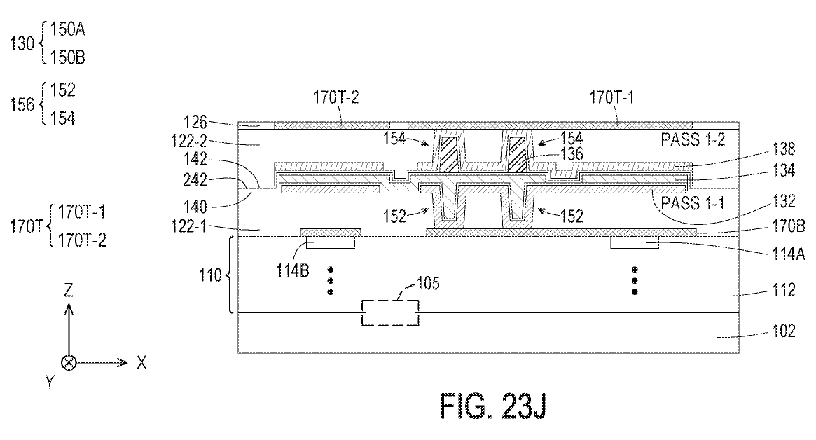

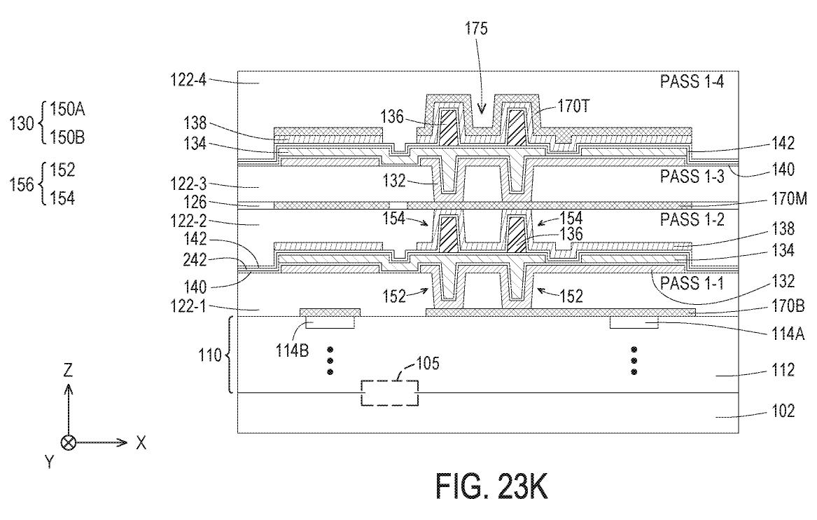

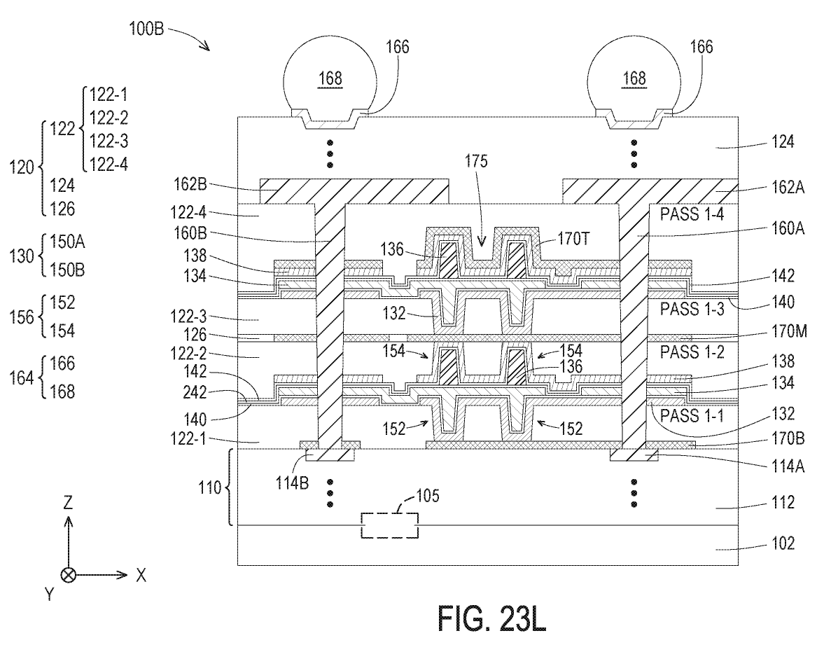

FIGS. 23A–23L are diagrammatic cross-sectional views of an IC structure, such as IC structure 100B of FIG. 2, in portion or entirety, at various stages of fabrication of a stacked capacitor structure thereof, such as capacitor structure 130, according to various aspects of the present disclosure. FIGS. 23A–23L have been simplified for the sake of clarity to better understand the inventive concepts of the present disclosure. Additional steps can be provided before, during, and after the various stages of fabrication, and some of the steps described can be moved, replaced, or eliminated for additional embodiments of the various stages of fabrication. Additional features can be added in the IC structure, and some of the features described below can be replaced, modified, or eliminated in other embodiments of the IC structure.

Referring to FIG. 23A, an extra metal plate, such as EBP 170B, is formed over an MLI structure, such as MLI structure 110, as described above with reference to FIG. 23A. Referring to FIG. 23B, a passivation layer, such as passivation sublayer 122-1, may be formed over EBP 170B and MLI structure 110 (e.g., insulation layer 112 thereof), and trenches, such as a trench 306A and a trench 306B, that expose EBP 170B (e.g., EBP segment 170B-1 thereof) may be formed therein, as described above with reference to FIG. 23B.

Referring to FIG. 23C, electrode layers, such as electrode layer 132 and electrode layer 134, and an insulator layer, such as an insulator layer 140, may be formed over passivation sublayer 122-1 that combine to fill trench 306A and trench 306B, as described above with reference to FIG. 23C. After forming electrode layer 134, another insulator layer, such as insulator layer 242, may be formed over electrode layer 134 and insulator layer 140. The insulator layer may partially fill an opening in electrode layer 134 between electrode segment 134-1 and electrode segment 134-2, and the insulator layer may electrically isolate electrode segment 134-1 from electrode segment 134-2. The insulator layer is formed by CVD, PVD, ALD, other suitable process, or combinations thereof. A thickness of the insulator layer is less than a thickness of electrode layer 134. In some embodiments, a thickness of the insulator layer (and thus insulator layer 242) is about 40 Å to about 80 Å. In some embodiments, the insulator layer (and thus insulator layer 242) is a high-k dielectric layer, such as described herein.

Referring to FIGS. 23D–23G, after forming as insulator layer 242, another electrode layer, such as electrode layer 136, is formed, over electrode layer 134 and insulator layer 242, as described with reference to FIGS. 23D–23G. Referring to FIG. 23H, after forming electrode layer 136, another insulator layer, such as insulator layer 142, is formed over electrode layer 136 and insulator layer 242, as described above with reference to FIG. 23H. Referring to FIG. 23I, another electrode layer, such as electrode layer 138, may be formed over insulator layer 142, and a passivation layer, such as passivation sublayer 122-2 may be formed over electrode layer 138, as described above with reference to FIG. 23H. Referring to FIG. 23J, an extra metal plate, such as EMP 170M, is formed over capacitor stack 150A, as described above with reference to FIG. 23I. Referring to FIG. 23K, capacitor stack 150B may be formed over capacitor stack 150A and EMP 170M, as described above with reference to FIG. 23J. Referring to FIG. 23L, processing may further include forming additional features and/or components of IC structure 100B (e.g., passivation sublayer 122-4, passivation layer 124, metal via 160A, metal via 160B, RDL line 162A, RDL line 162B, connectors 164, etc.) as described above with reference to FIG. 23K.

The present disclosure provides for many different embodiments. For example, though embodiments described herein include and/or depict 6 MIM capacitor structures, the present disclosure contemplates other configurations, such as 9 MIM capacitor structures, which may include another group of MIM units 156 stacked on the top group of MIM units 156 (e.g., including capacitor stacks 150B), or other MIM capacitor structure configurations. In some embodiments, a device structure includes a passivation structure and a stacked capacitor structure disposed in the passivation structure. The stacked capacitor structure includes a capacitor stack. The capacitor stack includes a first metal-insulator-metal (MIM) stack disposed over a second MIM stack. The first MIM stack has a first profile and the second MIM stack has a second profile different from the first profile. The stacked capacitor structure further includes a metal plate disposed on an electrode of the capacitor stack. The device structure further includes a via structure disposed in the passivation structure. The via structure extends through the capacitor stack and the metal plate, and the metal plate extends from the electrode of the capacitor stack to the via structure. In some embodiments, the first MIM stack is a pillar MIM stack and the second MIM stack is a trench MIM stack.

In some embodiments, a portion of the passivation structure is disposed between the metal plate and the electrode of the capacitor stack. In some embodiments, the metal plate is a first metal plate, the electrode is a bottom electrode of the capacitor stack, and the stacked capacitor structure further includes a second metal plate disposed on a top electrode of the capacitor stack. The second metal plate extends from the top electrode of the capacitor stack to the via structure, and the via structure extends through the second metal plate. In some embodiments, the capacitor stack is a first capacitor stack, the electrode is a top electrode of the capacitor stack, and the stacked capacitor structure further includes a second capacitor stack that includes a third MIM stack disposed over a fourth MIM stack. In such embodiments, the metal plate is disposed on a bottom electrode of the second capacitor stack, the metal plate extends from the bottom electrode of the second capacitor stack to the via structure, and the via structure extends through the second capacitor stack. In some embodiments, the capacitor stack further includes an insulator layer disposed between the first MIM stack and the second MIM stack. In some embodiments, the capacitor stack is a capacitor unit of an array of capacitor units of the stacked capacitor structure. In some embodiments, the capacitor stack is a three-dimensional structure, and the metal plate is a planar structure.

In some embodiments, a method of fabricating a capacitor structure includes forming a capacitor stack in a passivation structure. The capacitor stack includes a pillar metal-insulator-metal (MIM) stack disposed over a trench MIM stack. The method further includes forming a metal structure on an electrode of the capacitor stack and forming a via structure that extends through the capacitor stack and the metal structure. In some embodiments, forming the via structure includes forming a first via that extends through a top electrode of the pillar MIM stack and a bottom electrode of the trench MIM stack and forming a second via that extends through a top electrode of the trench MIM stack. In such embodiments, the electrode of the capacitor stack may be the top electrode of the pillar MIM stack, the bottom electrode of the trench MIM stack, or both. In some embodiments, forming the metal structure includes forming a metal layer before the capacitor stack and forming the capacitor stack on the metal layer. In such embodiments, the electrode of the capacitor stack may be a bottom electrode. In some embodiments, forming the metal structure includes forming a metal layer after the capacitor stack, and the metal layer is formed over the capacitor stack. In such embodiments, the electrode of the capacitor stack may be a top electrode. In some embodiments, the capacitor stack is a first capacitor stack, the pillar MIM stack is a first pillar MIM stack, the trench MIM stack is a first trench MIM stack, and the method further includes forming a second capacitor stack in the passivation structure. The second capacitor stack is formed above the first capacitor stack, the second capacitor stack includes a second pillar MIM stack disposed over a second trench MIM stack, and the via structure extends through the second capacitor stack. In some embodiments, forming the metal structure includes forming a metal layer on the first capacitor stack and forming the second capacitor stack on the metal layer. In some embodiments, forming the metal structure includes forming a metal layer, forming the first capacitor stack on the metal layer, and forming the second capacitor stack on the first capacitor stack.

In some embodiments, a method of fabricating a capacitor structure includes depositing and patterning a metal layer to form a metal plate over a metal line of a multilayer interconnect structure. The metal line is disposed in an insulator layer of the multilayer interconnect structure. The method further includes forming a three-dimensional capacitor stack in a passivation structure. The metal plate is embedded in the passivation structure, an electrode of the three-dimensional capacitor stack extends over the metal line of the multilayer interconnect structure, and the metal plate extends from the electrode of the three-dimensional capacitor stack to over the metal line of the multilayer interconnect structure. The method further includes forming a via that extends through the electrode of the three-dimensional capacitor stack, through the metal plate, and to the metal line of the multilayer interconnect structure. In some embodiments, forming the three-dimensional capacitor stack includes forming a first metal-insulator-metal (MIM) stack having a first profile and a second MIM stack having a second profile different from the first profile. In some embodiments, the metal layer is a first metal layer, the metal plate is a first plate, the electrode is a first electrode of the three-dimensional capacitor stack, and the method further includes depositing and patterning a second metal layer to form a second metal plate. The second metal plate is embedded in the passivation structure, a second electrode of the three-dimensional capacitor stack extends over the metal line of the multilayer interconnect structure, the second metal plate extends from the second electrode of the three-dimensional capacitor stack to over the metal line of the multilayer interconnect structure, and the via further extends through the second metal plate. In some embodiments, the method includes providing the metal plate with a planar structure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A device structure comprising:
a passivation structure;
a stacked capacitor structure disposed in the passivation structure, wherein the stacked capacitor structure includes:
a capacitor stack that includes a first metal-insulator-metal (MIM) stack disposed over a second MIM stack, wherein the first MIM stack has a first profile and the second MIM stack has a second profile different from the first profile, and
a metal plate disposed on an electrode of the capacitor stack; and
a via structure disposed in the passivation structure, wherein the via structure extends through the capacitor stack and the metal plate and the metal plate extends from the electrode of the capacitor stack to the via structure.

2. The device structure of claim 1, wherein the first MIM stack is a pillar MIM stack and the second MIM stack is a trench MIM stack.

3. The device structure of claim 1, wherein a portion of the passivation structure is disposed between the metal plate and the electrode of the capacitor stack.

4. The device structure of claim 1, wherein the metal plate is a first metal plate, the electrode is a bottom electrode of the capacitor stack, and the stacked capacitor structure further includes a second metal plate disposed on a top electrode of the capacitor stack, wherein the second metal plate extends from the top electrode of the capacitor stack to the via structure and the via structure extends through the second metal plate.

5. The device structure of claim 1, wherein the capacitor stack is a first capacitor stack, the electrode is a top electrode of the capacitor stack, and the stacked capacitor structure further includes a second capacitor stack that includes a third MIM stack disposed over a fourth MIM stack, wherein the metal plate is disposed on a bottom electrode of the second capacitor stack, the metal plate extends from the bottom electrode of the second capacitor stack to the via structure, and the via structure extends through the second capacitor stack.

6. The device structure of claim 1, wherein the capacitor stack further includes an insulator layer disposed between the first MIM stack and the second MIM stack.

7. The device structure of claim 1, wherein the capacitor stack is a capacitor unit of an array of capacitor units of the stacked capacitor structure, wherein in a top view, the capacitor units are uniformly spaced along a first direction and have varying lengths along a second direction that is different from the first direction.

8. The device structure of claim 1, wherein the capacitor stack is a three-dimensional structure, and the metal plate is a planar structure.

9. A method of fabricating a capacitor structure, the method comprising:
forming a capacitor stack in a passivation structure, wherein the capacitor stack includes a pillar metal-insulator-metal (MIM) stack disposed over a trench MIM stack;
forming a metal structure on an electrode of the capacitor stack, wherein the forming of the metal structure includes depositing and etching at least one metal layer; and
forming a via structure that extends through the capacitor stack and the metal structure.

10. The method of claim 9, wherein the forming the via structure includes:
forming a first via that extends through a top electrode of the pillar MIM stack and a bottom electrode of the trench MIM stack, wherein the electrode of the capacitor stack is the top electrode of the pillar MIM stack, the bottom electrode of the trench MIM stack, or both; and
forming a second via that extends through a top electrode of the trench MIM stack.

11. The method of claim 9, wherein the forming the metal structure includes forming a metal layer before the capacitor stack and forming the capacitor stack on the metal layer, wherein the electrode of the capacitor stack is a bottom electrode.

12. The method of claim 9, wherein the forming the metal structure includes forming a metal layer after the capacitor stack, wherein the metal layer is formed over the capacitor stack and the electrode of the capacitor stack is a top electrode.

13. The method of claim 9, wherein the capacitor stack is a first capacitor stack, the pillar MIM stack is a first pillar MIM stack, the trench MIM stack is a first trench MIM stack, and the method further includes:
forming a second capacitor stack in the passivation structure, wherein the second capacitor stack is formed above the first capacitor stack, the second capacitor stack includes a second pillar MIM stack disposed over a second trench MIM stack, and the via structure extends through the second capacitor stack.

14. The method of claim 13, wherein forming the metal structure includes forming a metal layer on the first capacitor stack and forming the second capacitor stack on the metal layer.

15. The method of claim 13, wherein forming the metal structure includes forming a metal layer, forming the first capacitor stack on the metal layer, and forming the second capacitor stack on the first capacitor stack.

16. A method of fabricating a capacitor structure, the method comprising:
depositing and patterning a metal layer to form a metal plate over a metal line of a multilayer interconnect structure, wherein the metal line is disposed in an insulator layer of the multilayer interconnect structure;
forming a three-dimensional capacitor stack in a passivation structure, wherein the metal plate is embedded in the passivation structure, an electrode of the three-dimensional capacitor stack extends over the metal line of the multilayer interconnect structure, and the metal plate extends from the electrode of the three-dimensional capacitor stack to over the metal line of the multilayer interconnect structure; and
forming a via that extends through the electrode of the three-dimensional capacitor stack, through the metal plate, and to the metal line of the multilayer interconnect structure.

17. The method of claim 16, wherein the forming the three-dimensional capacitor stack includes forming a first metal-insulator-metal (MIM) stack having a first profile and a second MIM stack having a second profile different from the first profile.

18. The method of claim 16, wherein the metal layer is a first metal layer, the metal plate is a first plate, the electrode is a first electrode of the three-dimensional capacitor stack, and the method further includes:
depositing and patterning a second metal layer to form a second metal plate, wherein the second metal plate is embedded in the passivation structure, a second electrode of the three-dimensional capacitor stack extends over the metal line of the multilayer interconnect structure, the second metal plate extends from the second electrode of the three-dimensional capacitor stack to over the metal line of the multilayer interconnect structure, and the via further extends through the second metal plate.

19. The method of claim 16, further comprising configuring the depositing and the patterning of the metal layer to provide the metal plate with a planar structure.

20. The method of claim 16, further comprising configuring the depositing and the patterning of the metal layer to provide the metal plate with a structure that conforms to the electrode of the three-dimensional capacitor stack.
